(19) United States
(12) Patent Application Publication
(10) Pub. No.: US 2026/0202333 A1
(43) Pub. Date: Jul. 16, 2026

(54) DETERMINATION METHOD, STORAGE MEDIUM, SUBSTRATE PROCESSING APPARATUS, AND INFORMATION PROCESSING APPARATUS

(71) Applicant: Tokyo Electron Limited, Tokyo (JP)

(72) Inventors: Hirokazu UEDA, Osaka-shi (JP); Hiroyuki KOISHI, Tokyo (JP); Yasutoshi UMEHARA, Tokyo (JP)

(21) Appl. No.: 19/437,865

(22) Filed: Dec. 31, 2025

Related U.S. Application Data
(63) Continuation of application No. PCT/JP2024/022347, filed on Jun. 20, 2024.

(30) Foreign Application Priority Data
Jul. 4, 2023 (JP) 2023-109790

(51) Int. Cl. G01N 21/3563; G01N 21/956

(52) U.S. Cl. CPC G01N 21/3563; G01N 21/956; G01N 2021/3568

(57) ABSTRACT

A determination method includes: (a) performing spectroscopic measurement of a substrate, in which a pattern including a recess is formed and a filling material is filled in the recess, to measure either one of an absorbance spectrum or a reflectance spectrum of the substrate; and (b) determining a filled state of the recess from an integral value of a spectral value for each wavelength range of a plurality of wavelength ranges of the one spectrum of the substrate measured in step (a), by using a model generated by performing machine learning on data associating a plurality of filled states of recesses with integral values of spectral values for each wavelength range of the one spectrum of a plurality of substrates in which the filling material is filled.

### CROSS-REFERENCE TO RELATED APPLICATIONS

The application is a Bypass Continuation Application of PCT International Application No. PCT/JP2024/022347, filed on Jun. 20, 2024 and designating the United States, the international application being based upon and claiming the benefit of priority from Japanese Patent Application No. 2023-109790, filed on Jul. 4, 2023, the entire contents of which are incorporated herein by reference.

### TECHNICAL FIELD

The present disclosure relates to a determination method, a storage medium, a substrate processing apparatus, and an information processing apparatus.

### BACKGROUND

Patent Document 1 below discloses a substrate processing method including: “a primary step of supplying a process gas onto a substrate for semiconductor device manufacturing having a recess formed therein to form a third layer, and filling the recess with the third layer, the substrate in which a surface of a first layer is exposed on a top surface of the substrate and a second layer is exposed on at least a sidewall of the recess having the sidewall and a bottom surface; an etching step of etching the third layer and stopping the etching in a state where the top surface of the substrate is exposed and the third layer remains in the recess; and a secondary step of supplying the process gas onto the substrate to form the third layer and filling the recess with the third layer, wherein when the process gas is supplied, an incubation time on the surface of the first layer is longer than an incubation time on the surface of the second layer.”

### PRIOR ART DOCUMENTS

### Patent Documents

Patent Document 1: Japanese Laid-Open Patent Publication No. 2017-174902

### SUMMARY

According to one embodiment of the present disclosure, there is provided a determination method including: (a) performing spectroscopic measurement of a substrate, in which a pattern including a recess is formed and a filling material is filled in the recess, to measure either one of an absorbance spectrum or a reflectance spectrum of the substrate; and (b) determining a filled state of the recess from an integral value of a spectral value for each wavelength range of a plurality of wavelength ranges of the one spectrum of the substrate measured in step (a), by using a model generated by performing machine learning on data associating a plurality of filled states of recesses with integral values of spectral values for each wavelength range of the one spectrum of a plurality of substrates in which the filling material is filled.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic cross-sectional view showing an example of a schematic configuration of a film forming apparatus according to an embodiment.

FIG. 2 is a view showing a state in which a substrate is raised from a stage in the film forming apparatus according to the embodiment.

FIG. 3 is a schematic configuration view showing another example of the film forming apparatus according to the embodiment.

FIG. 4 is a diagram showing an example of a schematic configuration of a control device according to the embodiment.

FIG. 5 is a view illustrating an example of a substrate before film formation according to the embodiment.

FIG. 6 is a view showing an example of the substrate after film formation according to the embodiment.

FIG. 7 is a view illustrating an example of an index for a filled state of a recess according to the embodiment.

FIG. 8A is a view illustrating an example of an index of a state of a base of the substrate according to the embodiment.

FIG. 8B is a view illustrating an example of an index of the state of the base of the substrate according to the embodiment.

FIG. 9 is a view illustrating an example of data stored in training data according to the embodiment.

FIG. 10 is a view illustrating an example of data stored in training data according to the embodiment.

FIG. 11A is a diagram schematically illustrating an example of an overall flow of a determination method according to the embodiment.

FIG. 11B is a diagram schematically illustrating another example of the overall flow of the determination method according to the embodiment.

FIG. 11C is a diagram schematically illustrating another example of the overall flow of the determination method according to the embodiment.

FIG. 11D is a diagram schematically illustrating another example of the overall flow of the determination method according to the embodiment.

FIG. 11E is a diagram schematically illustrating another example of the overall flow of the determination method according to the embodiment.

FIGS. 12A and 12B are diagrams showing an example of an S/N ratio of a reflectance spectrum.

FIG. 13 is a flowchart showing an example of a flow of a generating process including a generating step of the determination method according to the embodiment.

FIG. 14 is a flowchart showing an example of a flow of a film forming process including a determining step of the determination method according to the embodiment.

FIG. 15 is a view showing an example of a cross-sectional structure of a substrate W used for verification.

FIG. 16A is a diagram illustrating verification results of Case 1.

FIG. 16B is a diagram illustrating verification results of Case 2.

FIG. 16C is a diagram illustrating verification results of Case 3.

FIG. 17 is a diagram illustrating verification results when a width of a wavelength range is varied.

FIG. 18 is a schematic configuration view showing another example of the film forming apparatus according to the embodiment.

FIG. 19 is a view showing an example of a schematic configuration of a measurer according to the embodiment.

FIG. 20 is a view showing another example of a schematic configuration of the measurer according to the embodiment.

FIG. 21 is a diagram showing an example of a schematic configuration of an information processing apparatus according to an embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Embodiments of a determination method, a storage medium, a substrate processing apparatus, and an information processing apparatus disclosed in the present disclosure are described in detail below with reference to the drawings. The disclosed determination method, storage medium, substrate processing apparatus, and information processing apparatus are not limited to these embodiments.

In the manufacture of semiconductor devices, a film forming apparatus forms a conductive film or an insulating film on a substrate, such as a semiconductor wafer, on which a pattern including a recess is formed. The film forming apparatus places the substrate in a chamber maintained at a predetermined vacuum degree, supplies a film-forming precursor gas into the chamber, and forms a film on the substrate using reaction-assisting energy such as heat or plasma. As film-forming techniques, for example, thermal CVD (Chemical Vapor Deposition), thermal ALD (Atomic Layer Deposition), PE-CVD (Plasma-Enhanced CVD), and PE-ALD (Plasma-Enhanced ALD) are known.

By the way, as miniaturization of semiconductor devices has advanced, recesses of patterns formed on a substrate have been miniaturized and their aspect ratios have increased. When a film forming process of filling a filling material into such recesses of the substrate is performed, there is a possibility that filling defects may occur in which the recesses are filled in a state in which cavities are formed in the recesses.

Accordingly, a technique for detecting the occurrence of the filling defects has been desired.

### Embodiments

### Apparatus Configuration

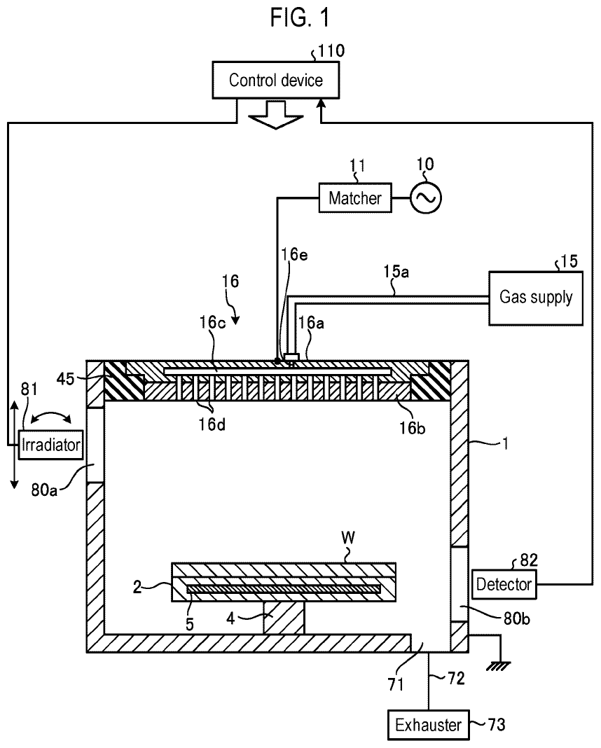

Next, an embodiment will be described. First, an example of a substrate processing apparatus according to the present disclosure will be described. In the following, the substrate processing apparatus of the present disclosure will be referred to as a film forming apparatus 100, and a case where film formation is performed as substrate processing by the film forming apparatus 100 will be mainly described. FIG. 1 is a schematic cross-sectional view showing an example of a schematic configuration of the film forming apparatus 100 according to an embodiment. In this embodiment, the film forming apparatus 100 corresponds to the substrate processing apparatus according to the present disclosure. In one embodiment, the film forming apparatus 100 is an apparatus for forming a film on a substrate W. The film forming apparatus 100 shown in FIG. 1 includes an airtight chamber 1 that is electrically set to a ground potential. The chamber 1 has a cylindrical shape and is made of, for example, aluminum having an anodized film formed on its surface, aluminum oxide, or the like. A stage 2 is provided within the chamber 1.

The stage 2 is made of metal or ceramic, such as aluminum, nickel, aluminum oxide, or aluminum nitride. The substrate W, such as a semiconductor wafer, is placed on an upper surface of the stage 2. The substrate W has a pattern including recesses formed therein. The stage 2 supports the placed substrate W horizontally. A lower surface of the stage 2 is electrically connected to a support member 4 made of a conductive material. The stage 2 is supported by the support member 4. The support member 4 is supported at a bottom surface of the chamber 1. A lower end of the support member 4 is electrically connected to the bottom surface of the chamber 1 and is grounded via the chamber 1. The lower end of the support member 4 may be electrically connected to the bottom surface of the chamber 1 via a circuit adjusted to reduce the impedance between the stage 2 and the ground potential.

The stage 2 has a built-in heater 5, which can heat the substrate W placed on the stage 2 to a predetermined temperature. The stage 2 may have a flow path (not shown) inside the stage for circulating a refrigerant, and the refrigerant whose temperature is controlled by a chiller unit installed outside the chamber 1 may be circulated and supplied through the flow path. The stage 2 may control the substrate W to a predetermined temperature by heating with the heater 5 and cooling with the refrigerant supplied from the chiller unit. The stage 2 may not be equipped with the heater 5 and may control the temperature of the substrate W solely with the refrigerant supplied from the chiller unit.

Further, an electrode may be embedded in the stage 2. A DC voltage applied to this electrode generates an electrostatic force, which allows the stage 2 to attract and hold the substrate W placed on the upper surface of the stage 2.

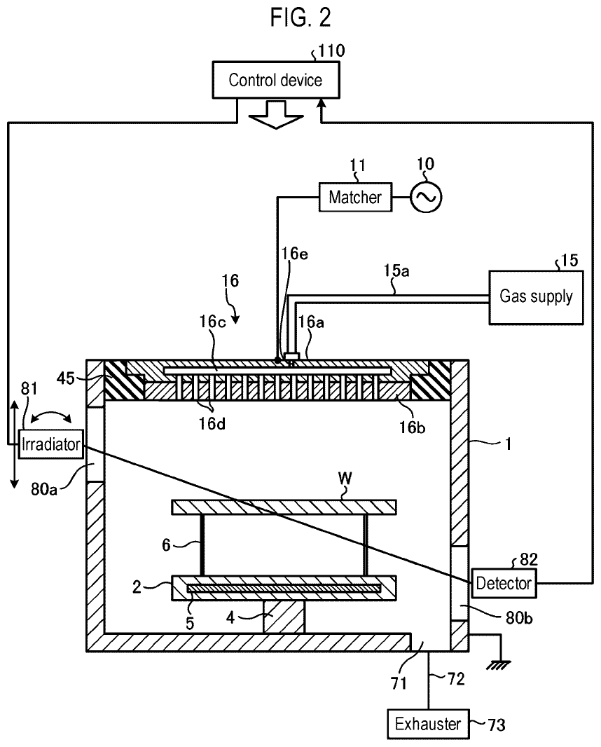

The stage 2 is provided with lifter pins 6 for raising and lowering the substrate W. FIG. 2 is a view showing a state in which the substrate W is raised from the stage 2 in the film forming apparatus 100 according to the embodiment. In the film forming apparatus 100, when transferring the substrate W or performing spectroscopic measurement on the substrate W, the lifter pins 6 are protruded from the stage 2, and a rear surface of the substrate W is supported by the lifter pins 6 to raise the substrate W from the stage 2. For example, a loading/unloading port (not shown) for loading/unloading the substrate W is provided on a sidewall of the chamber 1. A gate valve for opening/closing the loading/unloading port is provided at the loading/unloading port. When loading/unloading the substrate W, the gate valve is opened. The substrate W is loaded into the chamber 1 through the loading/unloading port by a transfer mechanism (not shown) in a transfer chamber. The film forming apparatus 100 controls a lifting mechanism (not shown) provided outside the chamber 1 to raise the lifter pins 6 and receive the substrate W from the transfer mechanism. After the transfer mechanism retracts, the film forming apparatus 100 controls the lifting mechanism to lower the lifter pins 6 and place the substrate W on the stage 2.

A substantially disc-shaped shower head 16 is provided above the stage 2 and on an inner surface of the chamber 1. The shower head 16 is supported above the stage 2 via an insulating member 45 such as ceramic. Accordingly, the chamber 1 and the shower head 16 are electrically insulated from each other. The shower head 16 is made of conductive metal such as nickel.

The shower head 16 includes a ceiling plate member 16a and a shower plate 16b. The ceiling plate member 16a is provided so as to close an interior of the chamber 1 from above. The shower plate 16b is provided below the ceiling plate member 16a so as to face the stage 2. A gas diffusion space 16c is formed in the ceiling plate member 16a. The ceiling plate member 16a and the shower plate 16b are formed with a number of dispersed gas discharge holes 16d that open toward the gas diffusion space 16c.

The ceiling plate member 16a is formed with a gas introduction hole 16e for introducing various gases into the gas diffusion space 16c. A gas supply path 15a is connected to the gas introduction hole 16e. A gas supply 15 is connected to the gas supply path 15a.

The gas supply 15 has gas supply lines respectively connected to gas supply sources for various gases used in film formation. Each gas supply line branches appropriately according to the film forming process and is provided with control devices for controlling gas flow rates, such as valves such as opening/closing valves and flow rate controllers such as mass flow controllers. The gas supply 15 is capable of controlling the flow rates of various gases by controlling the control devices such as the opening/closing valves and the flow rate controllers installed on each gas supply line.

The gas supply 15 supplies various gases used in film formation to the gas supply path 15a. For example, the gas supply 15 supplies a precursor gas for film formation to the gas supply path 15a. The gas supply 15 also supplies a purge gas and a reaction gas, which reacts with the precursor gas, to the gas supply path 15a. The gases supplied to the gas supply path 15a are diffused in the gas diffusion space 16c and discharged through the gas discharge holes 16d.

A space surrounded by a lower surface of the shower head 16 and the upper surface of the stage 2 forms a processing space where a film forming process is performed. The shower head 16 is paired with the stage 2 and functions as an electrode plate for generating capacitively-coupled plasma (CCP) in the processing space. A radio-frequency power supply 10 is connected to the shower head 16 via a matcher 11. To generate plasma in the processing space, the radio-frequency power supply 10 supplies radio-frequency power (RF power) in accordance with the supply of gas from the gas supply 15. As a result, the radio-frequency power is applied to the gas supplied from the shower head 16 to the processing space 40, thereby generating the plasma in the processing space. The radio-frequency power supply 10 may be connected to the stage 2 instead of the shower head 16, with the shower head 16 being grounded.

An exhaust port 71 is formed at the bottom of the chamber 1. An exhauster 73 is connected to the exhaust port 71 via an exhaust pipe 72. The exhauster 73 includes a vacuum pump and a pressure regulating valve. The exhauster 73 can reduce and adjust an internal pressure of the chamber 1 to a predetermined vacuum degree by operating the vacuum pump and the pressure regulating valve.

The film forming apparatus 100 performs spectroscopic measurement on the substrate W in the chamber 1, thereby enabling detection of a state of the film formed on the substrate W. The spectroscopic measurement includes a transmission method in which light is irradiated onto the substrate W and the light transmitted through the substrate W (transmitted light) is measured, and a reflection method in which light is irradiated onto the substrate W and the light reflected from the substrate W (reflected light) is measured. In spectroscopic measurement using the transmission method, an absorbance spectrum is measured. In spectroscopic measurement using the reflection method, a reflectance spectrum is measured. The absorbance spectrum represents the amount of light absorbed by a film at each wavelength when the light passes through the film. The reflectance spectrum represents a change in reflectance caused by light being absorbed or attenuated in a film when light reflects from the substrate W at the surface or underlying layer of the film, expressed as the amount of light reflected at each wavelength.

The film forming apparatus 100 shown in FIG. 1 illustrates an example of a configuration capable of spectroscopic measurement using the transmission method. The chamber 1 has windows 80a and 80b on its sidewalls facing each other across the stage 2. The window 80a is located at a high position on the sidewall. The window 80b is located at a low position on the sidewall. The windows 80a and 80b are fitted and sealed with a light-transmissive member, such as quartz. An irradiator 81 for irradiating light is provided outside the window 80a. A detector 82 capable of detecting light is provided outside the window 80b. In this embodiment, the irradiator 81 and the detector 82 correspond to a measurer in the present disclosure.

When performing the spectroscopic measurement using the transmission method, as shown in FIG. 2, the film forming apparatus 100 protrudes the lifter pins 6 from the stage 2 to raise the substrate W from the stage 2. The positions of the window 80a and the irradiator 81 are adjusted so that the light emitted from the irradiator 81 is irradiated onto the upper surface of the raised substrate W through the window 80a. The positions of the window 80b and the detector 82 are also adjusted so that the transmitted light transmitted though the raised substrate W is incident on the detector 82 through the window 80b.

In the spectroscopic measurement, measurement light used for measurement is preferably light having a wavelength that is easily transmitted to the substrate W. For example, if the substrate W is a silicon substrate, the measurement light is preferably infrared light that is transparent to silicon substrates. Furthermore, for example, when forming a SiO film or a SiN film as a filling material by CVD, the measurement light may be short-wavelength light below infrared light, for example, light in the visible light range. In particular, if the depth of the recess formed in the substrate W is relatively shallow, the measurement light may be short-wavelength light of approximately 0.1 μm to 0.22 μm, or visible light.

When detecting the state of the film formed on the substrate W, the irradiator 81 emits the measurement light. The irradiator 81 is located so that the emitted measurement light strikes a predetermined region in a vicinity of the center of the raised substrate W through the window 80a. The detector 82 is located so that transmitted light that has transmitted through the predetermined region of the substrate W is incident through the window 80b. The detector 82 detects the transmitted light that has transmitted through the substrate W.

The irradiator 81 incorporates a light source that emits measurement light, as well as optical elements such as mirrors and lenses, and is capable of emitting interfered measurement light. For example, the irradiator 81 splits the optical path of the measurement light, generated by the light source and before being emitted to the outside, into two optical paths using a half mirror or the like. The irradiator 81 then varies the optical path length of one of the two optical paths relative to the optical path length of the other to cause interference, thereby emitting measurement light of various interference waves with different optical path differences. The irradiator 81 may also be provided with a plurality of light sources, and measurement light from each light source may be controlled by optical elements to emit measurement light of various interference waves with different optical path differences.

The film forming apparatus 100 detects filling defects of the film formed on the substrate W from the transmitted light detected by the detector 82. Specifically, the film forming apparatus 100 calculates the absorbance spectrum of the transmitted light detected by the detector 82. The film forming apparatus 100 then detects the filling defects of the film formed on the substrate W from an integral value of absorbance for each of a plurality of wavelength ranges of the absorbance spectrum.

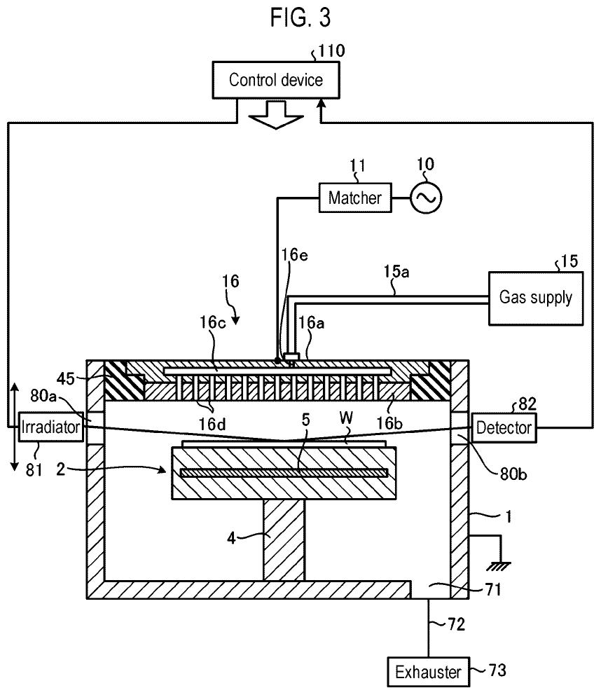

Here, FIGS. 1 and 2 illustrate an example in which the film forming apparatus 100 is configured to perform the spectroscopic measurement using the transmission method. However, the film forming apparatus 100 may also be configured to be capable of spectroscopic measurement using the reflection method. FIG. 3 is a schematic configuration view showing another example of the film forming apparatus 100 according to the embodiment. The film forming apparatus 100 shown in FIG. 3 illustrates an example in which the film forming apparatus 100 is configured to measure the reflected light from the substrate W.

In the film forming apparatus 100 illustrated in FIG. 3, the windows 80a and 80b are provided on the sidewalls of the chamber 1 at positions facing each other across the stage 2. The irradiator 81 that emits light is provided outside the window 80a. The detector 82 that can detect the light is provided outside the window 80b. The positions of the window 80a and the irradiator 81 are adjusted so that the light emitted from the irradiator 81 is irradiated onto the substrate W through the window 80a. The positions of the window 80b and the detector 82 are adjusted so that the light reflected by the substrate W is incident on the detector 82 through the window 80b. A loading/unloading port (not shown) is provided on the sidewall of the chamber 1 different from the windows 80a and 80b for loading/unloading the substrate W. A gate valve for opening/closing the loading/unloading port is provided at this loading/unloading port.

When detecting filling defects, the irradiator 81 emits measurement light. The irradiator 81 is located so that the emitted measurement light strikes a predetermined region in a vicinity of the center of the substrate W through the window 80a. The detector 82 is located so that the reflected light reflected from the predetermined region of the substrate W is incident through the window 80b. The detector 82 detects the reflected light reflected from the substrate W. In this way, the film forming apparatus 100 illustrated in FIG. 3 is capable of spectroscopic measurement using the reflectance method. In the spectroscopic measurement using the reflectance method, a reflectance spectrum indicating the reflectance for each wavelength is obtained from the reflected light.

The film forming apparatus 100 may be configured to be capable of changing the angle of incidence and irradiation position of the measurement light incident on the substrate W from the irradiator 81. For example, in FIGS. 1 and 3, the irradiator 81 is configured to be vertically movable and rotatable by a drive mechanism (not shown), thereby changing the angle of incidence and irradiation position of the measurement light incident on the substrate W from the irradiator 81.

The operation of the film forming apparatus 100 configured as described above is comprehensively controlled by a control device 110. The control device 110 controls each part of the film forming apparatus 100.

### Device Configuration of Control Device 110

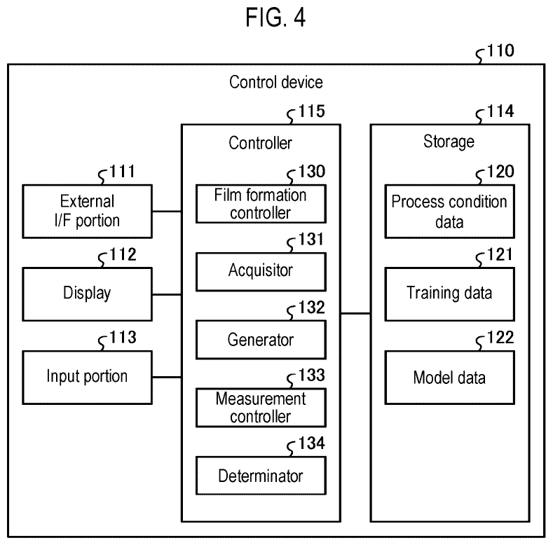

Next, an example of the configuration of the control device 110 according to the embodiment will be described. FIG. 4 is a diagram showing an example of the schematic configuration of the control device 110 according to the embodiment. The control device 110 is, for example, an information processing apparatus such as a computer.

The control device 110 includes an external I/F (interface) 111, a display 112, an input portion 113, a storage 114, and a controller 115. In addition to the functional parts shown in FIG. 4, the control device 110 may also include various other functional units commonly found in known computers.

The external I/F portion 111 is an interface for inputting/outputting information to/from other devices. For example, the external I/F portion 111 is an interface for performing communication control with other devices. One example of the external I/F portion 111 may include a network interface card such as a LAN card. For example, the external I/F portion 111 transmits/receives various data to/from the film forming apparatus 100 and other apparatus via a network. The external I/F portion 111 may be, for example, an interface such as a USB (Universal Serial Bus) port.

The display 112 is a display device for displaying various information. Examples of the display 112 may include display devices such as an LCD (Liquid Crystal Display) and a CRT (Cathode Ray Tube). The display 112 displays various information.

The input portion 113 is an input device for inputting various information. Examples of the input portion 113 may include a mouse and a keyboard. The input portion 113 receives operation input from an administrator or the like and inputs operation information indicating the received operation contents to the controller 115.

The storage 114 is a storage device for storing various data. For example, the storage 114 is a non-transitory computer readable storage device (storage medium) such as a hard disk, an SSD (Solid State Drive), or an optical disc. The storage 114 may also be a semiconductor memory that enables data to be rewritten, such as a RAM (Random Access Memory), a flash memory, or a NVSRAM (Non-Volatile Static Random Access Memory).

The storage 114 stores an OS (Operating System) and various programs executed by the controller 115. For example, the storage 114 stores programs for executing a generating process and a film forming process which will be described later. Furthermore, the storage 114 stores various data used by the programs executed by the controller 115. For example, the storage 114 stores process condition data 120, training data 121, and model data 122. The storage 114 can also store other data in addition to the data listed above. Furthermore, various programs and data may be stored on a non-transitory computer-readable storage medium (e.g., a hard disk, an optical disc such as a DVD, a flexible disk, a semiconductor memory, etc.). Furthermore, various programs and data can be transmitted from other devices on demand and used online.

The process condition data 120 is data that stores process conditions for substrate processing performed on substrates W. In this embodiment, the process condition data 120 stores the process conditions for the film forming process performed on the substrate W. The process conditions include the type and flow rate of a process gas used during film formation and the power of the radio-frequency power supplied from the radio-frequency power supply 10. The training data 121 is data for training used to generate a prediction model. Details of the training data 121 will be described later. The model data 122 is data of prediction model for predicting the filled state.

The controller 115 is a device that controls the control device 110. The controller 115 can be an electronic circuit such as a CPU (Central Processing Unit) or an MPU (Micro Processing Unit), or an integrated circuit such as an ASIC (Application Specific Integrated Circuit) or an FPGA (Field Programmable Gate Array). The controller 115 has an internal memory for storing programs and data. The controller 115 reads various programs stored in the storage 114 and executes the processing of the read programs. The controller 115 functions as various processing parts through the execution of the programs. For example, the controller 115 includes a film formation controller 130, an acquisitor 131, a generator 132, a measurement controller 133, and a determinator 134. In this embodiment, an example will be described in which the controller 115 includes the film formation controller 130, the acquisitor 131, the generator 132, the measurement controller 133, and the determinator 134. However, the functions of the film formation controller 130, the acquisitor 131, the generator 132, the measurement controller 133, and the determinator 134 may be distributed among a plurality of controllers.

The film formation controller 130 controls each part of the film forming apparatus 100 to control the film forming process.

The acquisitor 131 acquires various information. For example, the acquisitor 131 displays an input screen on the display 112 and acquires various information by receiving input of various information from the input portion 113. The acquisitor 131 also acquires various information from other devices via a network (not shown). For example, the acquisitor 131 acquires information on the state of the base of the substrate W, the filled state of a recess 91 in each substrate W, and the thickness of the film formed on the substrate W.

Here, a brief description will be given of a flow of the film forming process performed on the substrate W as substrate processing by the film forming apparatus 100 according to the embodiment under the control of the film formation controller 130. When performing the film forming process in the film forming apparatus 100, the substrate W is placed on the stage 2 by a transfer mechanism such as a transfer arm (not shown). The substrate W has a pattern including recesses formed therein. When performing the film forming process on the substrate W, the film formation controller 130 controls the exhauster 73 to reduce the internal pressure of the chamber 1. The film formation controller 130 controls the gas supply 15 to supply various gases used for film formation from the gas supply 15 to introduce a process gas into the chamber 1 through the shower head 16. The film formation controller 130 then controls the radio-frequency power supply 10 to supply the radio-frequency power from the radio-frequency power supply 10 to generate plasma in the processing space, thereby forming a film on the substrate W.

By the way, as miniaturization of semiconductor devices has advanced, recesses of patterns formed on a substrate W have been miniaturized and their aspect ratios have increased. For example, in the VLSI (Very Large-Scale Integration) semiconductor manufacturing process, miniaturization has already progressed to the nanometer (nm) range, and market demands for even higher integration are driving not only miniaturization but also 3D design. When the film forming process is performed to fill the recesses of such a substrate W with a filling material, there is a possibility that filling defects may occur in which the recesses are filled in a state where cavities are formed in the recesses. Such cavities are referred to as voids or seams. Hereinafter, cavities formed in the recesses are also referred to as voids.

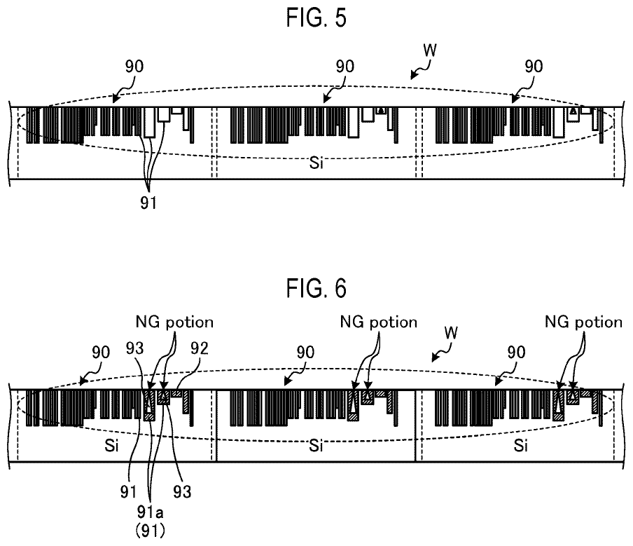

FIG. 5 is a view illustrating an example of the substrate W before film formation according to the embodiment. FIG. 5 shows a schematic cross-section of the substrate W. The substrate W is made of, for example, silicon (Si). Patterns 90, each corresponding to an area that will become a chip of a semiconductor device, are formed on the substrate W. Each pattern 90 includes recesses 91 of various shapes and depths. FIG. 6 is a view showing an example of the substrate W after film formation according to the embodiment. FIG. 6 schematically shows a state in which a film 92 has been formed on the pattern 90 having the recesses 91. As a result of the film formation, some recesses 91a of the substrate W are not completely filled with the film 92, and voids 93, which are cavities, are formed in the recesses 91a. In FIG. 6, the recesses 91 with the voids 93 formed therein are indicated as “NG positions.”

Accordingly, the film forming apparatus 100 according to the embodiment performs the spectroscopic measurement on the substrate W on which a film has been formed, to measure either the absorbance spectrum or the reflectance spectrum of the substrate W. For example, if the film forming apparatus 100 is configured to enable the spectroscopic measurement using the transmission method, as shown in FIGS. 1 and 2, the film forming apparatus 100 measures the absorbance spectrum of the substrate W. Alternatively, if the film forming apparatus 100 is configured to enable the spectroscopic measurement using the reflection method, as shown in FIG. 3, the film forming apparatus 100 measures the reflectance spectrum of the substrate W. The film forming apparatus 100 determines the filled state of the recesses 91 of the substrate W from the results of the spectroscopic measurement using a prediction model that predicts the filled state of the recesses 91 of the substrate W.

The film forming apparatus 100 according to the embodiment generates the prediction model using machine learning. For example, the storage 114 stores the training data 121 used to generate the prediction model. The training data 121 stores data associating the filled state of the recesses 91 with the integral values of the spectral values for each wavelength range among a plurality of wavelength ranges of either the absorbance spectrum or the reflectance spectrum of a plurality of substrates W filled with a filling material. For example, when the film forming apparatus 100 performs the spectroscopic measurement using the transmission method, the training data 121 stores data associating the filled state of the recesses 91 with the integral values of the absorbance for each wavelength range among a plurality of wavelength ranges of the absorbance spectrum of the plurality of substrates W filled with the filling material. Furthermore, when the film forming apparatus 100 performs the spectroscopic measurement using the reflection method, the training data 121 stores data associating the filled state of the recesses 91 with the integral values of the reflectance for each wavelength range among a plurality of wavelength ranges of the reflectance spectrum of the plurality of substrates W filled with the filling material. The training data 121 may be generated by the film forming apparatus 100 or may be received from another apparatus. For example, the film forming apparatus 100 performs a film forming process on the plurality of substrates W sequentially in advance to fill the plurality of substrates W with the filling material. The film forming apparatus 100 also performs the spectroscopic measurements on the plurality of substrates W filled with the filling material, and calculates either the absorbance spectrum indicating the absorbance at each wavelength or the reflectance spectrum indicating the reflectance at each wavelength for each of the plurality of substrates W. For example, when the film forming apparatus 100 performs the spectroscopic measurements using the transmission method, the film forming apparatus 100 performs the spectroscopic measurements on the plurality of substrates W filled with the filling material, and calculates the absorbance spectrum. For example, when the film forming apparatus 100 performs the spectroscopic measurements using the reflection method, the film forming apparatus 100 performs the spectroscopic measurements on the plurality of substrates W filled with the filling material, and calculates the reflectance spectrum.

The film forming apparatus 100 also acquires the filled state of the recesses 91 of each of the plurality of substrates W. For example, an inspector, such as a user, responsible for inspecting the filled state inspects the plurality of substrates W filled with the filling material using the film forming apparatus 100 to determine the filled state of the recesses 91. For example, the inspector checks SEM images of the cross sections of the substrates W and indexes the filled state of the recesses 91.

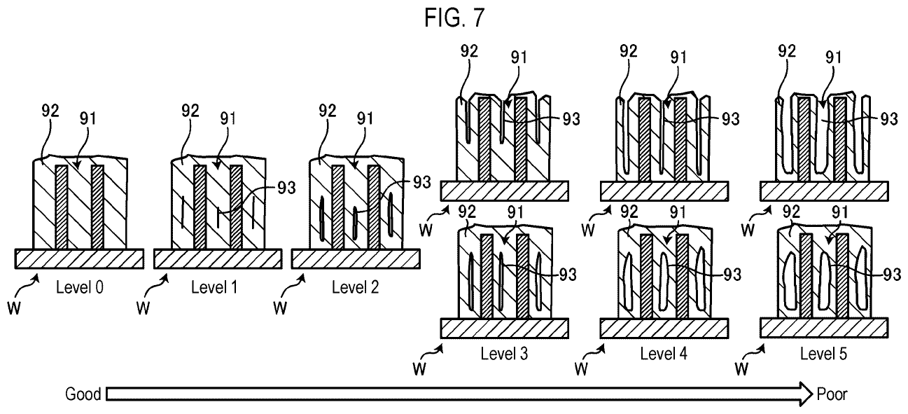

FIG. 7 is a view illustrating an example of an index for the filled state of a recess 91 according to the embodiment. FIG. 7 illustrates a state in which a film 92 made of a filling material is formed to fill a recess 91 of a substrate W. In FIG. 7, the filled state is classified into six levels from level 0 to level 5, with level 0 representing a good filled state in which the recess 91 is filled without any gaps, and level 5 representing a poor filled state, such as when large voids 93 are present in the recess 91. For example, an inspector checks a SEM image of a cross section of the substrate W and, referring to FIG. 7, indexes the filled state of the recess 91 of the substrate W as a filling index value having six levels ranging from level 0 to level 5. The inspector may also index the filled state of the recess 91 into fewer levels (2 to 5 levels) of filling index values. Further, the inspector may also index the filled state of the recess 91 into more levels than six filling index values. Furthermore, the indexing of the filled state of the recess 91 may be implemented by software. For example, image recognition may be performed on the SEM image of the cross section of the substrate W to identify an area of void 93 contained in the recess 91, and the filled state of the recess 91 may be indexed based on the shape and size of the identified area of void 93.

The acquisitor 131 acquires the filled state of the recesses 91 for each of the plurality of substrates W. For example, the acquisitor 131 displays an input screen on the display 112 and receives input of the filling index values for each of the plurality of substrates W from the input portion 113, thereby acquiring the filled state of the recesses 91 for each of the plurality of substrates W. The acquisitor 131 associates the filled state of the recesses 91 with the integral values of the spectral values for each wavelength range among a plurality of wavelength ranges of either the absorbance spectrum or the reflectance spectrum for each of the plurality of substrates W filled with the filling material, and stores the associated data in the storage 114 as the training data 121. For example, when the film forming apparatus 100 performs the spectroscopic measurement using the transmission method, the acquisitor 131 associates the filling index values with the integral values of absorbance for each wavelength range of the absorbance spectrum for each of the plurality of substrates W, and stores the associated data in the storage 114 as the training data 121. Further, when the film forming apparatus 100 performs the spectroscopic measurement using the reflection method, the acquisitor 131 associates the filling index values with the integral values of reflectance for each wavelength range of the reflectance spectrum for each of the plurality of substrates W, and stores the associated data in the storage 114 as the training data 121.

The generator 132 performs machine learning on the training data 121 to generate a prediction model. The generator 132 stores data of the generated prediction model in the storage 114 as the model data 122.

The film forming apparatus 100 according to the embodiment performs the spectroscopic measurement on the substrates W on which the film has been formed, and determines the filled state of the recesses 91 of the substrates W from the results of the spectroscopic measurement using the prediction model.

For example, the measurement controller 133 controls the spectroscopic measurement on the substrate W. For example, the measurement controller 133 controls the irradiator 81 and the detector 82 to emit the measurement light from the irradiator 81 and detect the light transmitted through the substrate W or reflected by the substrate W using the detector 82. The detector 82 outputs signal intensity data of the detected light to the control device 110. The measurement controller 133 performs spectroscopic analysis, such as a Fourier transform, on the signal intensity data input from the detector 82, and calculates either the absorbance spectrum or the reflectance spectrum. For example, when the film forming apparatus 100 performs the spectroscopic measurement using the transmission method, the measurement controller 133 calculates the absorbance spectrum from the signal intensity data input from the detector 82. Further, when the film forming apparatus 100 performs the spectroscopic measurement using the reflection method, the measurement controller 133 calculates the reflectance spectrum from the signal intensity data input from the detector 82.

The determinator 134 uses the prediction model to predict the state of the film formed on the substrate W from either one of the calculated spectra. The determinator 134 calculates spectral values for each wavelength range among a plurality of wavelength ranges of either one of the spectra. For example, when the film forming apparatus 100 performs the spectroscopic measurement using the transmission method, the determinator 134 calculates the integral values of absorbance for each wavelength range of the absorbance spectrum of the substrate W. Further, for example, when the film forming apparatus 100 performs the spectroscopic measurement using the reflection method, the determinator 134 calculates the integral values of reflectance for each wavelength range of the reflectance spectrum of the substrate W. The determinator 134 uses the prediction model to predict the filled state of the recesses 91 of the substrate W from the integral values of the spectral values for each wavelength range. For example, when the film forming apparatus 100 performs the spectroscopic measurement using the transmission method, the determinator 134 uses the prediction model to predict the filled state of the recesses 91 of the substrate W from the integral values of absorbance for each wavelength range. Furthermore, for example, when the film forming apparatus 100 performs the spectroscopic measurement using the reflectance method, the determinator 134 uses the prediction model to predict the filled state of the recesses 91 of the substrate W from the integral values of reflectance for each wavelength range. The determinator 134 then determines the filled state of the recesses 91 of the substrate W based on the prediction results.

The training data 121 may further be associated with the film thickness of the filling material and the state of the base of the substrate W on which the filling material is formed. For example, the inspector inspects the plurality of substrates W to determine the state of the base on which the filling material is formed. The state of the base may be determined for the substrate W before or after the filling material is formed. For example, the inspector checks the SEM image of the cross section of the substrate W and indexes the state of the base on which the filling material is formed. Further, the plurality of substrates W in which the filling material is filled using the film forming apparatus 100 is inspected to measure the film thickness of the filling material. The acquisitor 131 acquires the film thickness of the filling material and the state of the base for each of the plurality of substrates W by receiving input of the film thickness of the filling material and the state of the base surface via the input portion 113. The acquisitor 131 associates the integral values of the spectral values for each wavelength range of the plurality of substrates W filled with the filling material, the filled state of the recesses 91, the film thickness of the filling material, and the state of the base with each other, and stores the associated data in the storage 114 as the training data 121. The generator 132 may generate a prediction model by performing machine learning on the training data 121 including the film thickness and the state of the base of the substrate W. The determinator 134 may use the prediction model to predict the state and thickness of the film formed on the substrate W from either the absorbance spectrum or the reflectance spectrum.

Here, a specific example will be described.

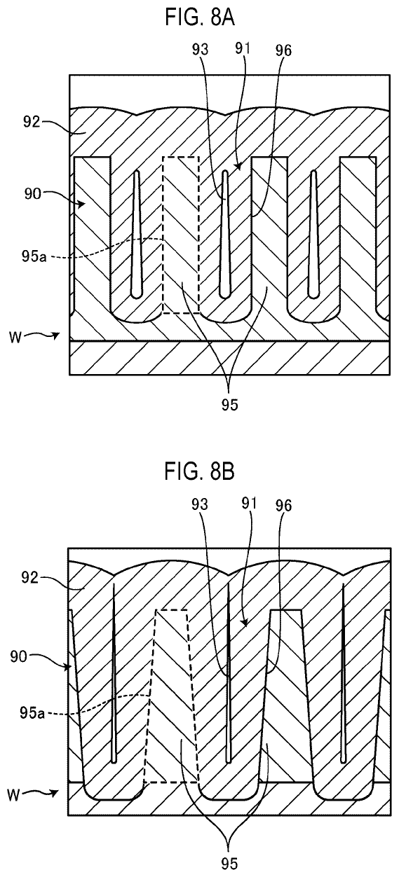

First, a specific example of indexing the state of the base of the substrate W will be described. FIGS. 8A and 8B are views illustrating an example of an index of the state of the base of the substrate W according to the embodiment. FIGS. 8A and 8B show a recess 91 of the substrate W filled with the filling material under the same film formation conditions. The substrate W has a plurality of protruding core material portions 95 formed as a pattern 90. The recess 91 is formed between the core material portions 95. In FIGS. 8A and 8B, the cross-sectional shape of one core material portion 95 is indicated by a broken line 95a. In FIG. 8A, the core material portions 95 are formed to have the same width in the vertical direction of the substrate W. Sidewalls 96 of the core material portions 95 are parallel to the vertical direction of the substrate W. In FIG. 8B, the core material portions 95 are formed in a tapered shape having a width narrowing toward the upper portion in the vertical direction of the substrate W. The sidewalls 96 of the core material portions 95 are oblique to the vertical direction of the substrate W. The filled state of the recess 91 varies depending on the state of the sidewall 96 that constitutes the recess 91 of the substrate W. For example, as shown in FIG. 8A, when the cross-sectional shape of the core material portion 95 is rectangular, since it is difficult for the filling material to reach a deep position in the recess 91 during film formation, voids 93 tend to be more likely to occur. On the other hand, as shown in FIG. 8B, when the cross-sectional shape of the core material portion 95 is tapered, since it is easy for the filling material to reach a deep position in the recess 91 during film formation, voids 93 are less likely to occur than in FIG. 8A, and even if voids 93 do occur, they tend to be smaller. Therefore, the substrate W is inspected to determine the state of the base of the substrate. For example, the inspector checks a SEM image of the cross section of the substrate W on which a film is to be formed, and indexes the state of the base of the substrate. For example, the inspector indexes the state of the base into two levels of base index values, where the state of the base is set to 0 when the sidewall 96 is parallel to the vertical direction of the substrate W, and the state of the base is set to 1 when the sidewall 96 is oblique to the vertical direction of the substrate W. The inspector may index the state of the base of the substrate W into base index values with more levels depending on the angle of the sidewall 96 relative to the vertical direction of the substrate W. The indexing of the state of the base may also be implemented by software. For example, image recognition may be performed on the SEM image of the cross section of the substrate W to identify an area of the base, and the state of the base may be indexed based on the shape of the identified area of the base.

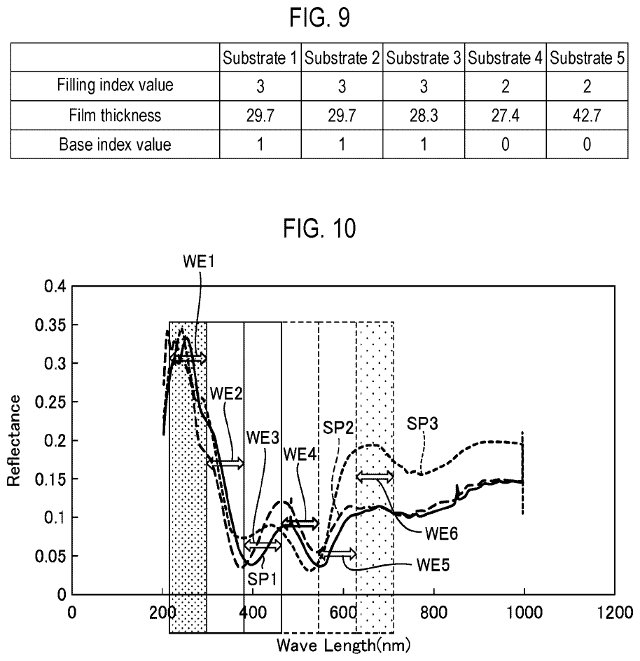

FIG. 9 is a diagram illustrating an example of data stored in the training data 121 according to the embodiment. FIG. 9 shows the filling index value, film thickness, and base index value for substrates 1 to 5 as an example of the plurality of substrates W.

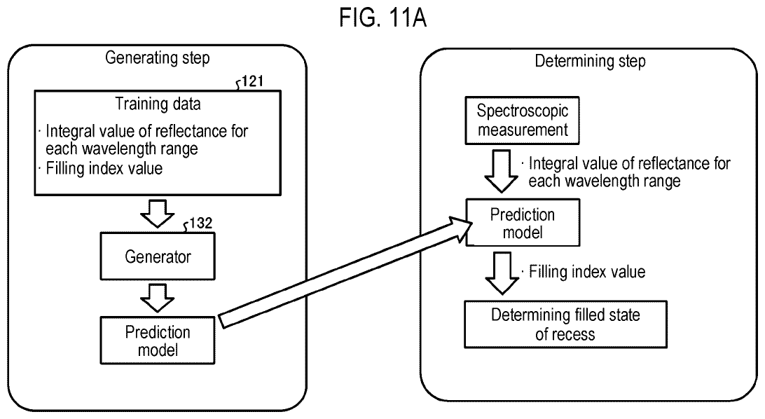

FIG. 10 is a diagram illustrating an example of data stored in the training data 121 according to the embodiment. FIG. 10 illustrates an example in which a reflectance spectrum is measured by the spectroscopic measurement using the film forming apparatus 100 configured to be capable of performing the spectroscopic measurement using the reflection method. FIG. 10 schematically shows the waveforms of reflectance spectra SP1 to SP3 of three substrates W. In the determination method according to this embodiment, for each substrate W, the integral values of reflectance for each wavelength range of a plurality of wavelength ranges of the reflectance spectrum of the substrate W are calculated. For example, in the determination method according to this embodiment, a predetermined wavelength is set as a reference wavelength, and the integral values of reflectance for each wavelength range before and after the reference wavelength are calculated. The reference wavelength is set to, for example, a wavelength at which a large change in absorbance occurs when the filling defects such as voids 93 occurs. For example, the reference wavelength is set to a wavelength at which the change in absorbance is the largest. The widths of the plurality of wavelength ranges are preferably in the range of 75 to 200 nm. The plurality of wavelength ranges is set to one to five segments, each continuous before and after the reference wavelength. In FIG. 10, the reference wavelength is set to 480 nm, the wavelength range width is set to 80 nm, three wavelength ranges before the reference wavelength and three wavelength ranges after the reference wavelength are set as wavelength ranges WE1 to WE6, and the integral values of reflectance for each of the wavelength ranges WE1 to WE6 are calculated. For example, in FIG. 10, the integral values of reflectance for each of the wavelength ranges WE1 to WE6 for the reflectance spectra SP1 to SP3 are calculated. The plurality of wavelength ranges may be ranges obtained by dividing a wavelength range in which the change in absorbance due to the filling defects such as voids 93 is large into ranges each having a certain wavelength width.

Returning to FIG. 4, the training data 121 stores the integral values of the spectral values for each wavelength range of a plurality of wavelength ranges of either the absorbance spectrum or the reflectance spectrum of the plurality of substrates W in association with the filled state of the recesses 91. For example, when the film forming apparatus 100 performs the spectroscopic measurement using the transmission method, the training data 121 stores the integral values of absorbance for each wavelength range of the absorbance spectra of the plurality of substrates W in association with the filled state of the recesses 91. Further, when the film forming apparatus 100 performs the spectroscopic measurement using the reflection method, the training data 121 stores the integral values of reflectance for each wavelength range of the reflectance spectra of the plurality of substrates W in association with the filled state of the recesses 91. For example, the training data 121 stores, for each substrate W, the integral values of reflectance for each of the wavelength ranges WE1 to WE6 of the reflectance spectra, as shown in FIG. 10, in association with the filling index value.

The generator 132 performs machine learning on the training data 121 to generate the prediction model. For example, the generator 132 performs machine learning on the training data 121 using a linear regression algorithm to generate the prediction model that learns the relationship between data in the training data 121. For example, the generator 132 generates the prediction model that learns the relationship between the integral value of the spectral value for each wavelength range and the filling index value using linear regression. For example, when the training data 121 is data associating the integral value of absorbance for each wavelength range with the filling index value, the generator 132 generates the prediction model that learns the relationship between the integral value of absorbance and the filling index value using linear regression. Further, for example, when the training data 121 is data associating the integral value of reflectance for each wavelength range with the filling index value, the generator 132 generates the prediction model that learns the relationship between the integral value of reflectance and the filling index value using linear regression.

Here, in this embodiment, the prediction model is generated using a linear regression algorithm as machine learning to prevent overfitting of the training data 121. However, more advanced machine learning algorithms, such as neural networks or more advanced regression analysis than linear regression, may also be used.

The determinator 134 uses the prediction model generated in this manner to determine the filled state of the recess 91 of the substrate W. The determinator 134 derives the filling index value from the prediction model using the integral value of the spectral value for each wavelength range as an explanatory variable and the filling index value as an objective variable. For example, when the prediction model is generated by machine-learning the relationship between the integral value of absorbance and the filling index value, the determinator 134 derives the filling index value from the prediction model using the integral value of absorbance for each wavelength range as the explanatory variable and the filling index value as the objective variable. Further, for example, when the prediction model is generated by machine learning the relationship between the integral value of reflectance and the filling index value, the determinator 134 derives the filling index value from the prediction model using the integral value of reflectance for each wavelength range as the explanatory variable and the filling index value as the objective variable. The determinator 134 determines the filled state of the recess 91 based on the derived filling index value. For example, if the derived filling index value is greater than a predetermined threshold, the determinator 134 determines that a filling defect has occurred.

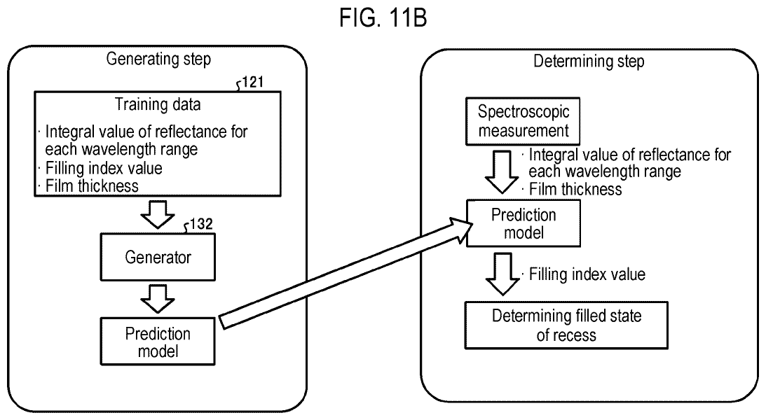

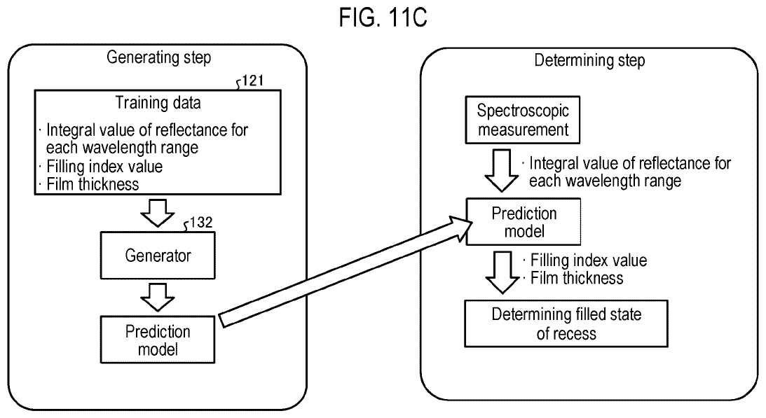

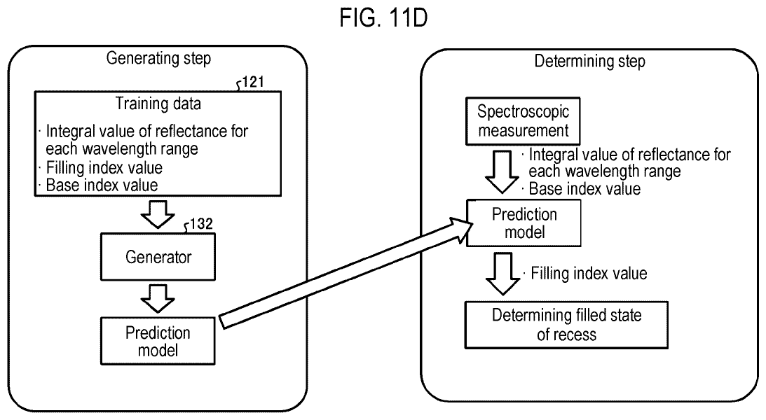

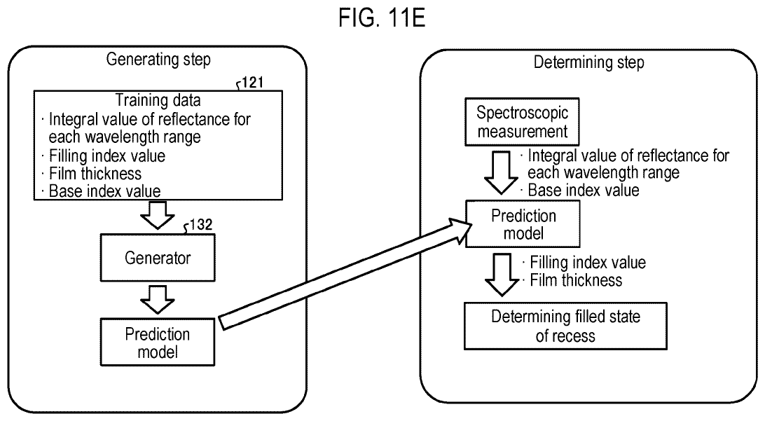

Next, an example of the overall flow of the determination method according to the embodiment will be described. The following description will be given using an example in which the film forming apparatus 100 is configured to perform the spectroscopic measurement using the reflectance method and the reflectance spectrum is measured by the spectroscopic measurement. FIG. 11A is a diagram schematically illustrating an example of the overall flow of the determination method according to the embodiment. FIG. 11A shows a case in which the prediction model is used to predict the filling index value from the integral value of reflectance. The determination method according to this embodiment is divided into a generating step for generating the prediction model and a determining step for determining the filled state of the recess 91 of the substrate W on which a film has actually been formed by using the prediction model.

The generating step is performed at least once before the determining step in order to generate the prediction model. In the generating step, the training data 121 is prepared. The training data 121 stores, for each of the plurality of substrates W, the integral value of reflectance for each wavelength range of the reflectance spectrum in association with the filling index value. In the generating step, the generator 132 performs machine learning on the training data 121 to generate the prediction model.

In the determining step, the spectroscopic measurement is performed on the substrate W on which the film has been formed in the film forming apparatus 100 to calculate the reflectance spectrum of the substrate W and to obtain the integral value of reflectance for each wavelength range of the reflectance spectrum of the substrate W. Then, in the determining step, the prediction model is used to predict the filled state of the substrate W from the integral value of reflectance for each wavelength range of the reflectance spectrum. For example, in the determining step, using the integral value of reflectance for each wavelength range as an explanatory variable and the filling index value as an objective variable, the filling index value is derived from the prediction model. The prediction model is generated by performing machine learning on the training data 121 associating the integral value of reflectance with the filling index value. Therefore, in the determining step, it is possible to predict the filling index value from the integral value of reflectance by using the prediction model. In the determining step, the filled state of the recess 91 is determined based on the derived filling index value. For example, if the derived filling index value is greater than a predetermined threshold, the determinator 134 determines that a filling defect has occurred.

The training data 121 may also be associated with the film thickness of the filling material or the state of the base of the substrate W. The prediction model may also be a model that learns the relationship between the film thickness and the state of the base of the substrate W.

FIG. 11B is a diagram schematically illustrating another example of the overall flow of the determination method according to the embodiment. FIG. 11B shows a case in which the prediction model is used to predict filling index value from the integral value of reflectance and the film thickness of the filling material. Since FIG. 11B is partially the same as FIG. 11A, the following description will mainly focus on the differences.

In the example of FIG. 11B, the training data 121 stores, for each of the plurality of substrates W, the integral value of reflectance for each wavelength range of the reflectance spectrum, the filling index value, and the film thickness of the filling material, in association with each other. In the generating step, the generator 132 performs machine learning on the training data 121 to generate the prediction model.

In the determining step, the spectroscopic measurement is performed on the substrate W on which the film has been formed in the film forming apparatus 100 to calculate the reflectance spectrum of the substrate W and to obtain the integral value of reflectance for each wavelength range of the reflectance spectrum of the substrate W. The film forming apparatus 100 also acquires the film thickness of the filling material. The film thickness may be acquired by measurement in the film forming apparatus 100, or may be acquired by measurement in another apparatus. Then, in the determining step, the prediction model is used to predict the filled state of the substrate W from the integral value of reflectance for each wavelength range of the reflectance spectrum and the film thickness of the filling material. For example, in the determining step, the filling index value is derived from the prediction model using the integral value of reflectance for each wavelength range and the film thickness of the filling material as explanatory variables and the filling index value as an objective variable. The prediction model is generated by performing machine learning on the training data 121 associating the integral value of reflectance, the filling index value, and the film thickness of the filling material. Therefore, in the determining step, it is possible to predict the filling index value from the integral value of reflectance and the film thickness of the filling material by using the prediction model. In the determining step, the filled state of the recess 91 is determined based on the derived filling index value.

FIG. 11C is a diagram schematically illustrating another example of the overall flow of the determination method according to the embodiment. FIG. 11C illustrates a case where the prediction model is used to predict the filling index value and the film thickness of the filling material from the integral value of reflectance. Since FIG. 11C is partially the same as FIGS. 11A and 11B, the following description will mainly focus on the differences.

In the example of FIG. 11C, like FIG. 11B, the training data 121 stores, for each of the plurality of substrates W, the integral value of reflectance for each wavelength range of the reflectance spectrum, the filling index value, and the film thickness of the filling material, in association with each other. In the generating step, the generator 132 performs machine learning on the training data 121 to generate the prediction model.

In the determining step, the spectroscopic measurement is performed on the substrate W on which the film has been formed in the film forming apparatus 100 to calculate the reflectance spectrum of the substrate W and to obtain the integral value of reflectance for each wavelength range of the reflectance spectrum of the substrate W. Then, in the determining step, the prediction model is used to predict the filled state of the substrate W and the film thickness of the filling material from the integral value of reflectance for each wavelength range of the reflectance spectrum. For example, in the determining step, the filling index value and the film thickness of the filling material are derived from the prediction model using the integral value of reflectance for each wavelength range as an explanatory variable and the filling index value and the film thickness of the filling material as objective variables. The prediction model is generated by performing machine learning on the training data 121 associating the integral value of reflectance, the filling index value, and the film thickness of the filling material. Therefore, in the determining step, it is possible to predict the filling index value and the film thickness of the filling material from the integral value of reflectance by using the prediction model. In the determining step, the filled state of the recess 91 is determined based on the derived filling index value. In the determining step, it may further be determined whether the film thickness of the filling material is within an appropriate range. For example, if the derived film thickness of the filling material is out of a predetermined range, the determinator 134 determines the film thickness to be defective.

FIG. 11D is a diagram schematically illustrating another example of the overall flow of the determination method according to the embodiment. FIG. 11D shows a case where the prediction model is used to predict the filling index value from the integral value of reflectance and the base index value. Since FIG. 11D is partially the same as FIG. 11A, the following description will mainly focus on the differences.

In the example of FIG. 11D, the training data 121 stores, for each of the plurality of substrates W, the integral value of reflectance for each wavelength range of the reflectance spectrum, the filling index value, and the base index value, in association with each other. In the generating step, the generator 132 performs machine learning on the training data 121 to generate the prediction model.

In the determining step, the spectroscopic measurement is performed on the substrate W on which the film has been formed in the film forming apparatus 100 to calculate the reflectance spectrum of the substrate W and to obtain the integral value of reflectance for each wavelength range of the reflectance spectrum of the substrate W. Then, in the determining step, the prediction model is used to predict the filled state of the substrate W from the integral value of reflectance for each wavelength range of the reflectance spectrum and the base index value. For example, in the determining step, the filling index value is derived from the prediction model using the integral value of reflectance for each wavelength range and the base index value as explanatory variables and the filling index value as an objective variable. The prediction model is generated by performing machine learning on the training data 121 associating the integral value of reflectance, the filling index value, and the base index value. Therefore, in the determining step, it is possible to predict the filling index value from the integral value of reflectance and the index value of the substrate by using the prediction model. In the determining step, the filled state of the recess 91 is determined based on the derived filling index value.

FIG. 11E is a diagram schematically illustrating another example of the overall flow of the determination method according to the embodiment. FIG. 11E shows a case in which the prediction model is used to predict the filling index value and the film thickness of the filling material from the integral value of reflectance and the base index value. Since FIG. 11E is partially the same as FIGS. 11A to 11D, the following description will mainly focus on the differences.

In the example of FIG. 11E, the training data 121 stores, for each of the plurality of substrates W, the integral value of reflectance for each wavelength range of the reflectance spectrum, the filling index value, the film thickness of the filling material, and the base index value, in association with each other. In the generating step, the generator 132 performs machine learning on such training data 121 to generate the prediction model.

In the determining step, the spectroscopic measurement is performed on the substrate W on which the film has been formed in the film forming apparatus 100 to calculate the reflectance spectrum of the substrate W and to obtain the integral value of reflectance for each wavelength range of the reflectance spectrum of the substrate W. Then, in the determining step, the prediction model is used to predict the filled state of the substrate W and the film thickness of the filling material from the integral value of reflectance for each wavelength range of the reflectance spectrum and the base index value. For example, in the determining step, the filling index value and the film thickness of the filling material are derived from the prediction model using the integral value of reflectance for each wavelength range and the base index value as explanatory variables and the filling index value and the film thickness of the filling material as objective variables. The prediction model is generated by performing machine learning on the training data 121 associating the integral value of reflectance, the filling index value, the film thickness of the filling material, and the base index value. Therefore, in the determining step, it is possible to predict the filling index value and the film thickness of the filling material from the integral value of reflectance and the base index value by using the prediction model. In the determining step, the filled state of the recess 91 is determined based on the derived filling index value. In the determining step, it may also be determined whether the film thickness of the filling material is within an appropriate range.

FIGS. 11A to 11E illustrate an example in which the film forming apparatus 100 is configured to perform the spectroscopic measurement using the reflection method and the reflectance spectrum is measured by the spectroscopic measurement. Even when the film forming apparatus 100 is configured to perform the spectroscopic measurement using the transmission method and the absorbance spectrum is measured by the spectroscopic measurement, the determination method according to the embodiment can be performed in the same manner as that shown in FIGS. 11A to 11E.

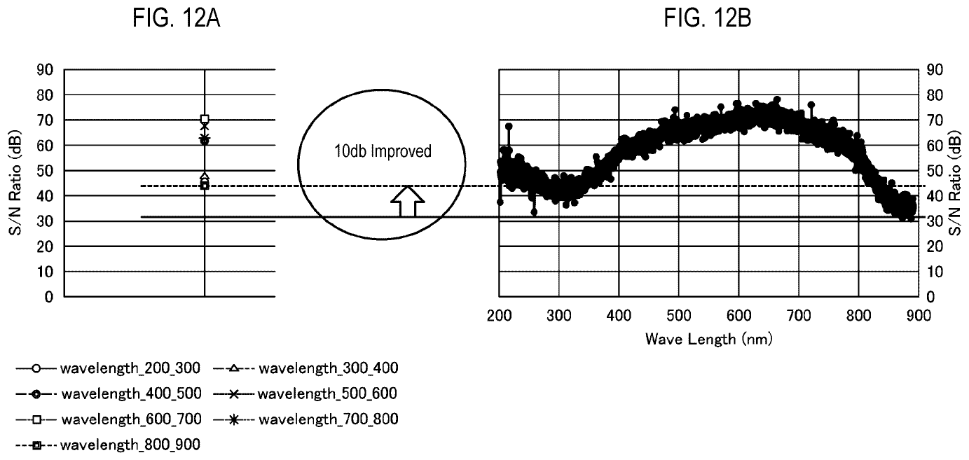

Next, the reason that the determination method according to the embodiment uses the integral value of the spectral value for each wavelength range, rather than the spectral value of the spectrum, will be explained. The following explanation uses a reflectance spectrum as an example. FIGS. 12A and 12B show an example of the S/N ratio of a reflectance spectrum. FIG. 12B shows the S/N ratio of the signal component(S) and noise component (N) included in the reflectance at each wavelength in the reflectance spectrum. FIG. 12A shows an example of the S/N ratio of the signal component(S) and noise component (N) included in the integral value of the reflectance for each wavelength range of the reflectance spectrum.

The reflectance spectrum measured by the spectroscopic measurement includes an effective signal component corresponding to the film state as well as a noise component such as white noise. Therefore, as shown in FIG. 12B, the reflectance spectrum fluctuates at each wavelength due to the noise component, with the signal component as a reference. The noise component fluctuates randomly within a certain numerical range, and the mean and variance of the entire data become zero.

FIG. 12A shows the S/N ratio of the integral value of reflectance for each 100 nm wavelength range for wavelengths from 200 nm to 900 nm in the reflectance spectrum. As described above, the noise component fluctuates randomly within a certain numerical range. Therefore, when the reflectance of each wavelength in the reflectance spectrum is integrated, the S/N ratio of the integrated reflectance value is reduced. This improves detection sensitivity. For example, in FIG. 12A, the detection sensitivity is improved by 10 dB as compared to FIG. 12B. While FIGS. 12A and 12B use the reflectance spectrum as an example, the S/N ratio of the integrated absorbance value is also reduced for the absorbance spectrum. Therefore, in the determination method according to the embodiment, the filled state of the recess 91 is determined using the integral value of either the absorbance spectrum or the reflectance spectrum.

Next, the process flow of the determination method according to the embodiment will be described. As described above, the determination method according to the embodiment is divided into the generating step and the determining step. Hereinafter, a case where the training data 121 is generated in the film forming apparatus 100 to generate the prediction model will be described.

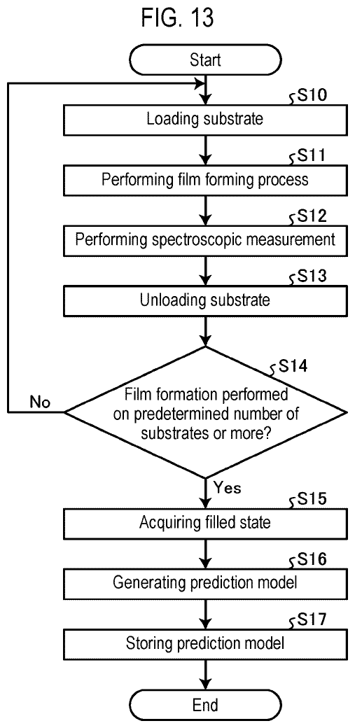

FIG. 13 is a flowchart showing an example of a flow of the generating process including the generating step of the determination method according to the embodiment.

The substrate W on which a pattern including recesses is formed is loaded into the film forming apparatus 100 by a transfer mechanism such as a transfer arm (not shown) and placed on the stage 2 (step S10). The film formation controller 130 controls each part of the film forming apparatus 100 to perform the film forming process (step S11).

The measurement controller 133 controls each part of the film forming apparatus 100 to perform the spectroscopic measurement of the substrate W (step S12). For example, the measurement controller 133 controls the irradiator 81 and the detector 82 to emit the measurement light from the irradiator 81 and detect the light transmitted through the substrate W or reflected by the substrate W using the detector 82. The detector 82 outputs signal intensity data of the detected light to the control device 110. The measurement controller 133 performs spectroscopic analysis, such as a Fourier transform, on the signal intensity data input from the detector 82 to calculate either one of the absorbance spectrum or the reflectance spectrum. The acquisitor 131 calculates the integral value of the spectral value for each wavelength range of the one spectrum and stores the integral value of the spectral value for each wavelength range of the one spectrum in the training data 121 for each substrate W. In this embodiment, step S12 corresponds to step (c) of the present disclosure. When the film forming apparatus 100 performs the spectroscopic measurement using the transmission method, the training data 121 stores the integral value of absorbance as the spectral value. When the film forming apparatus 100 performs the spectroscopic measurement using the reflection method, the training data 121 stores the integral value of reflectance as the spectral value.

The substrate W placed on the stage 2 is unloaded from the film forming apparatus 100 by a transfer mechanism (not shown) (step S13).

The generator 132 determines whether or not film formation has been performed on a predetermined number of substrates W or more (step S14). The predetermined number is determined in advance based on the number of substrates W required for the training data 121. If film formation has not been performed on the predetermined number of substrates W or more (step S14: “No”), the process proceeds to step S10 described above.

On the other hand, if film formation has been performed on the predetermined number of substrates W or more (Step S14: “Yes”), the acquisitor 131 acquires the filled state of the recesses 91 for each of the substrates W on which the film formation has been performed (step S15). For example, the acquisitor 131 displays an input screen on the display 112 and receives input of a filling index value for each of the substrates W from the input portion 113. The acquisitor 131 stores the input filling index value in the training data 121 in association with the integral value of the spectral value for each wavelength range for each substrate W. The acquisitor 131 may also acquire a film thickness and a base index value. For example, the acquisitor 131 may display an input screen on the display 112 and receive input of a film thickness and a base index value for each of the substrates W from the input portion 113. The acquisitor 131 may store the base index value in the training data 121 in association with the integral value of the spectral value for each wavelength range, the filling index value, and the film thickness for each substrate W. Alternatively, the acquisitor 131 may acquire the filling index value, film thickness, and base index value for each of plurality of substrates W via a network (not shown) from another device that stores the filling index value, the film thickness, and the base index value. In this embodiment, step S15 corresponds to steps (d), (f), and (g) of the present disclosure.

The generator 132 generates a prediction model by performing machine learning on the training data 121 (step S16). For example, the generator 132 performs the machine learning on the training data 121 using a linear regression algorithm to generate a prediction model that learns the relationship between data in the training data 121. In this embodiment, step S16 corresponds to step (e) of the present disclosure.

The generator 132 stores the data of the generated prediction model as the model data 122 in the storage 114 (step S17), and ends the generating process.

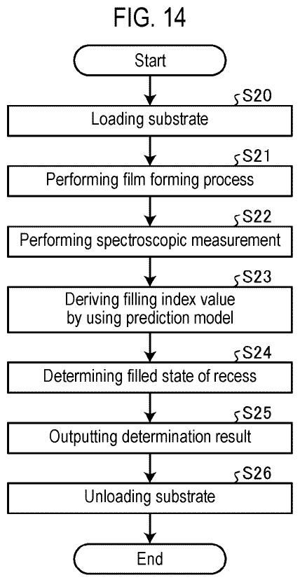

FIG. 14 is a flowchart showing an example of a flow of the film forming process including the determining step of the determination method according to the embodiment.

In the film forming apparatus 100, the substrate W on which a pattern including recesses is formed is loaded by a transfer mechanism such as a transfer arm (not shown) and placed on the stage 2 (step S20). The film formation controller 130 controls each part of the film forming apparatus 100 to perform the film forming process (step S21).

The measurement controller 133 controls each part of the film forming apparatus 100 to perform the spectroscopic measurement on the substrate W (step S22). For example, the measurement controller 133 controls the irradiator 81 and the detector 82 to emit the measurement light from the irradiator 81 and detect the light transmitted through or reflected by the substrate W using the detector 82. The detector 82 outputs signal intensity data of the detected light to the control device 110. The measurement controller 133 performs spectroscopic analysis such as a Fourier transform on the signal intensity data input from the detector 82 to calculate either one of the absorbance spectrum or the reflectance spectrum. For example, when the film forming apparatus 100 performs the spectroscopic measurement using the transmission method, the measurement controller 133 calculates the absorbance spectrum from the signal intensity data input from the detector 82. For example, when the film forming apparatus 100 performs the spectroscopic measurement using the reflection method, the measurement controller 133 calculates the reflectance spectrum from the signal intensity data input from the detector 82. In this embodiment, step S22 corresponds to step (a) of the present disclosure.

The determinator 134 reads the model data 122 and derives the filling index value from the one spectrum of the spectra using the prediction model of the read model data 122 (step S23). For example, when the prediction model has learned the relationship between the integral value of the spectral value and the filling index value, the determinator 134 derives the filling index value from the prediction model using the integral value of the spectral value for each wavelength range of the one spectrum as an explanatory variable and the filling index value as an objective variable. For example, when the film forming apparatus 100 performs the spectroscopic measurement using the transmission method, the determinator 134 uses the prediction model to derive the filling index value from the integral value of absorbance for each wavelength range. For example, when the film forming apparatus 100 performs the spectroscopic measurement using the reflection method, the determinator 134 uses the prediction model to derive the filling index value from the integral value of reflectance for each wavelength range.

The determinator 134 determines the filled state of the recess 91 based on the derived filling index value (step S24). For example, if the derived filling index value is greater than a predetermined threshold, the determinator 134 determines that a filling defect has occurred. In this embodiment, steps S23 and S24 correspond to step (b) of the present disclosure.

The determinator 134 outputs the determination result (step S25). For example, if the determinator 134 determines that a filling defect has occurred, it displays a message, which indicates that the filling defect has occurred, on the display 112. The determinator 134 also notifies an external device, such as a management terminal used by an administrator, of the occurrence of the filling defect.

The substrate W mounted on the stage 2 is unloaded from the film forming apparatus 100 by a transfer mechanism (not shown) (step S26), and the film forming process ends.

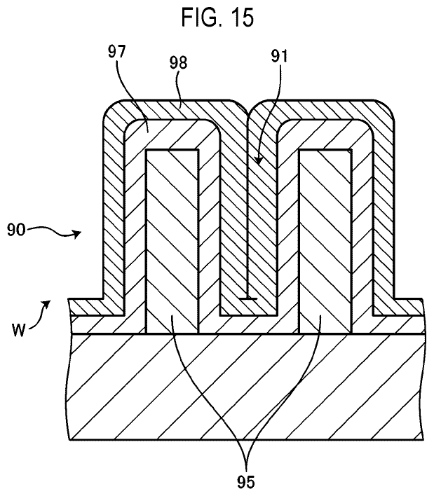

Next, a specific example of verification of the prediction results based on the prediction model will be described. The verification was performed by measuring the reflectance spectrum using the film forming apparatus 100 configured to perform the spectroscopic measurement using the reflection method. The verification was also performed using a plurality of substrates W each having a pattern 90 of approximately the same shape, including the recess 91, formed thereon. The filling material was filled in the plurality of substrates W using the film forming apparatus 100 under the same film formation conditions. FIG. 15 is a view showing an example of a cross-sectional structure of a substrate W used for verification. The substrate W is a silicon substrate or an amorphous silicon substrate. The substrate W has a plurality of core material portions 95 made of SiO and is entirely covered with an amorphous silicon film 97. The substrate W has the recess 91 formed between the core material portions 95 covered with the amorphous silicon film 97. The substrate W has a film made of SiN as a filling material, and the SiN film 98 covers the amorphous silicon film 97. The plurality of substrates W used in the verification include substrates with slightly different states of the base. For example, some of the plurality of substrates W used in the verification have core material portions 95 with tapered cross-sectional shapes.

In the verification, the spectroscopic measurement was performed on each of the plurality of substrates W filled with the filling material to calculate the reflectance spectrum to obtain the integral value of reflectance for each wavelength range of the reflectance spectrum of each substrate W. Furthermore, in the verification, SEM images of the cross sections of the plurality of substrates W filled with the filling material were examined to determine the filling index value, the film thickness of the filling material, and the base index value. For example, in the verification, the base index value was determined from a cross-sectional shape of the core material portion 95 which includes the amorphous silicon film 97. In the verification, the filling index value was determined from the filled state of the SiN film 98 in the recess 91. In the verification, the film thickness of the filling material was measured by measuring the film thickness of the SiN film 98 on the top of the core material portion 95.

First, a verification of Case 1 will be described. In Case 1, training substrates W were randomly selected from the plurality of substrates W, and the remaining substrates W were used as test substrates. In Case 1, for each training substrate W, the integral value of reflectance for each wavelength range of the reflectance spectrum, the filling index value, the film thickness of the filling material, and the base index value were associated and stored in the training data 121. In Case 1, such training data 121 was subjected to machine learning to generate a prediction model. Then, in Case 1, the generated prediction model was used to derive the filling index values for each training substrate W and each test substrate W. For example, in Case 1, using the integral value of reflectance for each wavelength range and the base index value as explanatory variables and the filling index value and the film thickness of the filling material as objective variables, the filling index value and the film thickness of the filling material were derived from the prediction model.

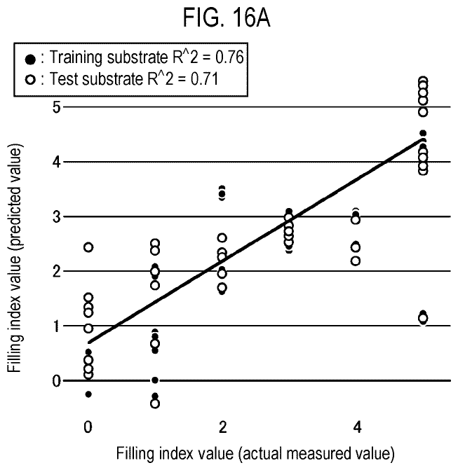

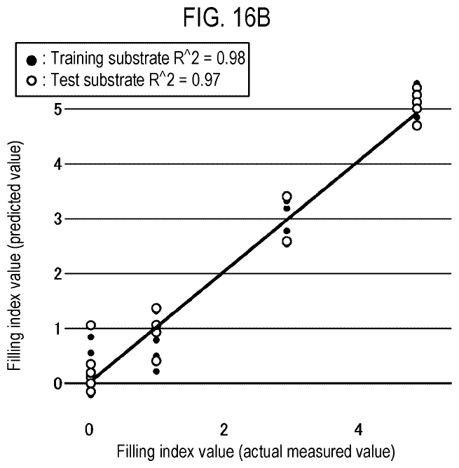

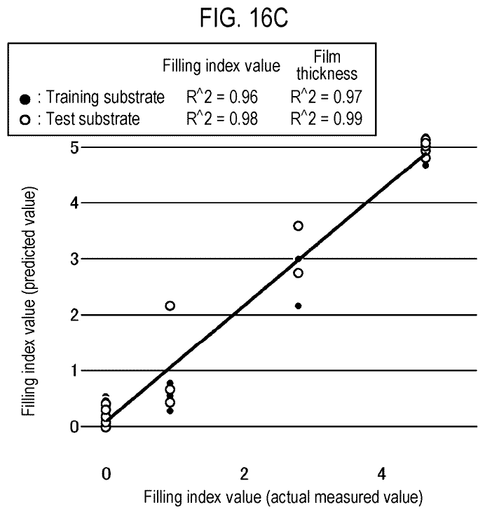

FIG. 16A is a diagram illustrating verification results of Case 1. FIG. 16A shows a graph with the previously determined filling index value (actual measured value) on the horizontal axis and the filling index value (predicted value) derived by the prediction model on the vertical axis. The verification results of the training substrate W and the test substrate W are plotted on the graph. The coefficient of determination R² between the actual measured value and the predicted value for the training substrate W is 0.76. The coefficient of determination R² between the actual measured value and the predicted value for the test substrate W is 0.71. The verification results of Case 1 indicate that even when the plurality of substrates W have slightly different states of the bases, the filling index value can be accurately derived by using the integral value of reflectance and the base index value as explanatory variables.

Next, a verification of Case 2 will be described. In Case 2, substrates W with the same state of the base (e.g., the base index value=0) were selected from the plurality of substrates W, some of the selected substrates W were used as training substrates W, and the remaining selected substrates W were used as test substrates W. In Case 2, for each training substrate W, the integral value of reflectance for each wavelength range of the reflectance spectrum, the filling index value, and the film thickness of the filling material were associated and stored in the training data 121. In Case 2, such training data 121 was subjected to machine learning to generate a prediction model. Then, in Case 2, the generated prediction model was used to derive the filling index values for each training substrate W and each test substrate W. For example, in Case 2, using the integral value of reflectance for each wavelength range and the film thickness of the filling material as explanatory variables and the filling index value as an objective variable, the filling index value was derived from the prediction model.

FIG. 16B is a diagram illustrating verification results of Case 2. FIG. 16B shows a graph with the previously determined filling index value (actual measured value) on the horizontal axis and the filling index value (predicted value) derived by the prediction model on the vertical axis. The verification results of the training substrate W and the test substrate W are plotted on the graph. The coefficient of determination R² between the actual measured value and the predicted value for the training substrate W is 0.98. The coefficient of determination R² between the actual measured value and the predicted value for the test substrate W is 0.97. Case 2 shows a case where substrates W having the same base index value are selected from the plurality of substrates W and the substrates W having the same state of the base are verified. Generally, in semiconductor manufacturing, substrates W with the same state of the base are transferred to the film forming apparatus 100, where a film such as a filling material is formed. The verification results for Case 2 indicate that for substrates W with the same state of the base, the filling index value can be predicted with high accuracy without using the base index value as an explanatory variable.

Next, a verification of Case 3 will be described. In Case 3, the prediction model generated in Case 2 was used to derive the filling index value and the film thickness of the filling material for each training substrate W and each test substrate W selected in Case 2. For example, in Case 3, using the integral value of reflectance for each wavelength range as an explanatory variable and the filling index value and the film thickness of the filling material as objective variables, the filling index value and the film thickness of the filling material were derived from the prediction model generated in Case 2.

FIG. 16C is a diagram illustrating verification results of Case 3. FIG. 16C shows a graph with the previously determined filling index value (actual measured value) on the horizontal axis and the filling index value (predicted value) derived by the prediction model on the vertical axis. The verification results of the training substrate W and the test substrate W are plotted on the graph. The coefficient of determination R² between the actual and predicted filling index values for the training substrate W is 0.96. The coefficient of determination R² between the actual and predicted filling index values for the test substrate W is 0.98. Further, for each training substrate W and each test substrate W, the film thickness (actual measured value) of the filling material determined in advance and the film thickness (predicted value) of the filling material derived by the prediction model were verified. The coefficient of determination R² between the actual measured value and the predicted value for the film thickness of the training substrate W is 0.97. The coefficient of determination R² between the actual measured value and the predicted value for the film thickness of the test substrate W is 0.99. The light transmittance and reflectance of the substrate W vary depending on the film thickness of the filling material. Therefore, the waveform of the reflectance spectrum obtained by the spectroscopic measurement of the substrate W shifts in accordance with the film thickness of the filling material. Therefore, there is a correlation between the integral value of reflectance for each wavelength range of the reflectance spectrum and the film thickness of the filling material. The verification results of Case 3 indicate that the filling index value and the film thickness of the filling material can be predicted with high accuracy from the integral value of reflectance for each wavelength range.

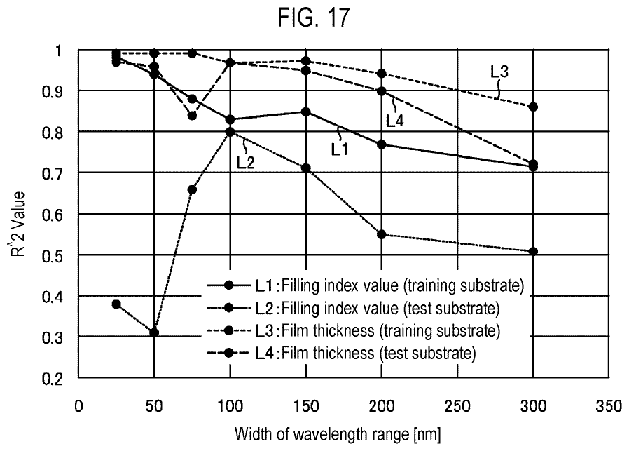

Next, a specific example of verification in which the width of the wavelength range over which reflectance is integrated is changed will be described. In the verification, the width of the wavelength range was varied within a range of 25 nm to 300 nm, and the verification of Case 3 was performed for each wavelength range width. FIG. 17 is a diagram illustrating verification results when the width of the wavelength range is varied. FIG. 17 shows a graph with the width of the wavelength range on the horizontal axis and the coefficient of determination R² on the vertical axis. The graph shows lines L1 to LA. Line L1 indicates a change in the coefficient of determination R² of the filling index value of the training substrate W as the width of the wavelength range is varied. Line L2 indicates a change in the coefficient of determination R² of the filling index value of the test substrate W as the width of the wavelength range is varied. Line L3 indicates a change in the coefficient of determination R² of the film thickness of the training substrate W as the width of the wavelength range is varied. Line L4 indicates a change in the coefficient of determination R² of the film thickness of the test substrate W as the width of the wavelength range is varied. As indicated by line L2, the coefficient of determination R² of the filling index value of the test substrate W varies significantly with the width of the wavelength range. For example, the coefficient of determination R² of the filling index value of the test substrate W decreases significantly when the wavelength range width is around 50 nm, and also tends to decrease as the wavelength range width increases. Therefore, the wavelength range width is preferably 75 to 200 nm, and more preferably 100 nm.

As described above, the determination method according to the embodiment includes steps (a) and (b). In step (a), the spectroscopic measurement is performed on the substrate W, in which the pattern 90 including the recesses 91 is formed and the filling material is filled in the recesses 91, to measure either one of the absorbance spectrum or the reflectance spectrum of the substrate W. In step (b), using a model generated by performing machine learning on data associating the integral value of the spectral value for each wavelength range of one of the spectra of the substrates W filled with the filling material with the filled state of the recesses 91, the filled state of the recesses 91 is determined from the integral value of the spectral value for each wavelength range of one of the spectra of the substrates W measured in step (a). This allows the determination method according to the embodiment to detect the occurrence of the filling defect.

In addition, the determination method according to the embodiment further includes steps (c), (d), and (e) before steps (a) and (b). In step (c), the spectroscopic measurement is performed on the plurality of substrates W filled with the filling material to measure one of the spectra of the plurality of substrates W. In step (d), a first index value (filling index value) that indexes the filled state of the recesses 91 of the plurality of substrates W is acquired. In step (e), a model (prediction model) is generated by performing machine learning on data associating the integral value of the spectral value for each wavelength range of one of the spectra measured in step (c) with the first index value acquired in step (d) for each of the plurality of substrates W. In step (b), using the integral value of the spectral value for each wavelength range of one spectrum of the substrate W measured in step (a) as an explanatory variable and the first index value as an objective variable, the first index value is derived from the model generated in step (e), and the filled state of the recesses 91 is determined based on the derived first index value.

This allows the determination method according to the embodiment to detect the occurrence of the filling defect.

Further, in step (e), the determination method according to the embodiment performs machine learning using a linear regression algorithm to generate the model that learns a relationship between the integral value of the spectral value for each wavelength range and the first index value. As a result, the determination method according to the embodiment can use the model to accurately detect the first index value associating with the filled state of the recesses 91, thereby accurately detecting the occurrence of the filling defect.

Furthermore, the determination method according to the embodiment further includes step (f) before step (e). In step (f), the film thickness of the filling material of the plurality of substrates W filled with the filling material is acquired. In step (e), the model is generated for each of the substrates W by performing machine training on data associating the integral value of the spectral value for each wavelength range of one of the spectra measured in step (c), the first index value acquired in step (d), and the film thickness acquired in step (f). In step (b), using the integral value of the spectral value for each wavelength range of one of the spectra of the substrate W measured in step (a) as an explanatory variable and the first index value and the film thickness as objective variables, the first index value and the film thickness are derived from the model generated in step (e). As a result, the determination method according to the embodiment can use the model to derive the film thickness in addition to the first index value.

Furthermore, the determination method according to the embodiment further includes step (g) before step (e). In step (g), a second index value (base index value) that indexes the base state of the plurality of substrates W filled with the filling material is acquired. In step (e), the model is generated for each of the plurality of substrates W by performing machine training on data associating the integral value of the spectral value for each wavelength range of one spectrum measured in step (c), the first index value acquired in step (d), and the second index value acquired in step (g). In step (b), using the integral value of the spectral value for each wavelength range of one spectrum of the substrate W measured in step (a) and the second index value as explanatory variables and the first index value as an objective variable, the first index value is derived from the model generated in step (e). As a result, the determination method according to the embodiment can use the model to accurately detect the first index value associated with the filled state of the recesses 91 even when the base state of the substrate W changes, thereby accurately detecting the occurrence of the filling defects.

Although the embodiments have been described above, the embodiments disclosed herein should be considered to be illustrative in all respects and not restrictive. Indeed, the above-described embodiments can be embodied in a variety of forms. Furthermore, the above-described embodiments may be omitted, substituted, or modified in various ways without departing from the scope and spirit of the claims.

For example, in the above embodiments, a case has been described in which the irradiator 81 is configured to be vertically movable and rotatable, thereby enabling the angle of incidence and irradiation position of light incident on the substrate W to be changed. However, the present disclosure is not limited thereto. For example, optical elements such as mirrors and lenses may be provided in an optical path of light emitted from the irradiator 81 or an optical path of light incident on the detector 82, so that the angle of incidence and irradiation position of light incident on the substrate W can be changed by the optical elements.

Furthermore, in the above embodiments, a case has been described in which the measurement light is transmitted through the vicinity of the center of the substrate W to determine the filled state in the vicinity of the center of the substrate W. However, the present disclosure is not limited thereto. For example, an optical element that reflects light may be provided in the chamber 1, and the optical element may irradiate a plurality of locations, such as the vicinity of the center of the substrate W and the vicinity of the periphery of the substrate W, with the measurement light, and the transmitted or reflected light may be detected at each location to determine the filled state at each of the plurality of locations on the substrate W.

Furthermore, in the above embodiments, a case has been described as an example in which the substrate processing apparatus of the present disclosure is a single-chamber type film forming apparatus 100 having one chamber. However, the present disclosure is not limited thereto. The substrate processing apparatus of the present disclosure may also be a multi-chamber type film forming apparatus having a plurality of chambers.

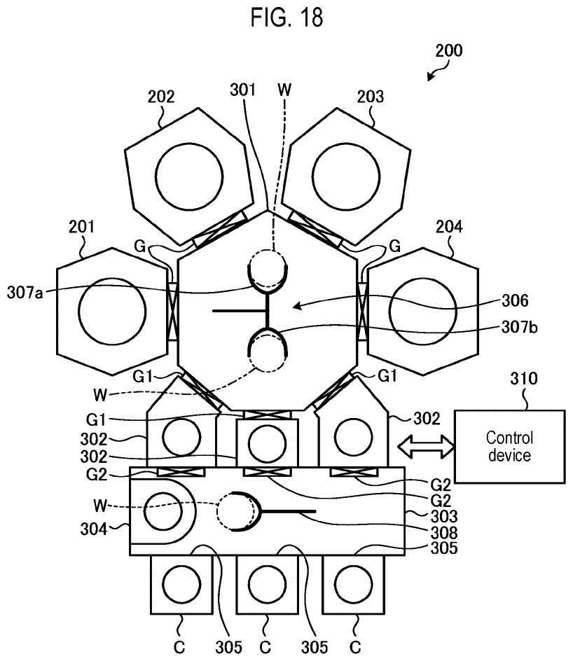

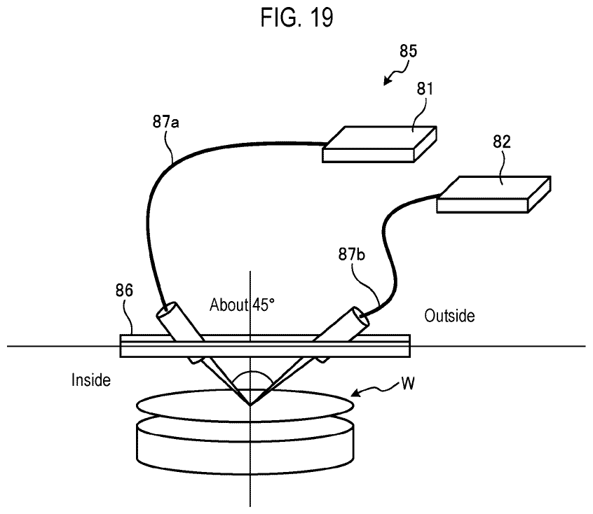

FIG. 18 is a schematic configuration view showing another example of the film forming apparatus 200 according to the embodiment. As shown in FIG. 18, the film forming apparatus 200 is a multi-chamber type film forming apparatus having four chambers 201 to 204. In the film forming apparatus 200, film forming processes are performed in the four chambers 201 to 204, respectively.

The chambers 201 to 204 are connected to four walls of a vacuum transfer chamber 301, which has a heptagonal planar shape, via gate valves G, respectively. An interior of the vacuum transfer chamber 301 is evacuated by a vacuum pump and maintained at a predetermined vacuum degree. Three load lock chambers 302 are connected to the other three walls of the vacuum transfer chamber 301 via gate valves G1, respectively. An atmospheric transfer chamber 303 is located on the opposite side of the vacuum transfer chamber 301 with the load lock chambers 302 therebetween. The three load lock chambers 302 are connected to the atmospheric transfer chamber 303 via gate valves G2, respectively. The load lock chambers 302 are each provided to control a pressure between atmospheric pressure and vacuum when transferring substrates W between the atmospheric transfer chamber 303 and the vacuum transfer chamber 301.

Three carrier installation ports 305 for installing carriers C (e.g., FOUPs) that accommodate substrates W are provided on the wall of the atmospheric transfer chamber 303 opposite the wall to which the load lock chambers 302 are attached. An alignment chamber 304 for aligning substrates W is provided on the side wall of the atmospheric transfer chamber 303. A downflow of clean air is formed within the atmospheric transfer chamber 303.

A transfer mechanism 306 is provided within the vacuum transfer chamber 301. The transfer mechanism 306 transfers substrates W to the chambers 201 to 204 and the load lock chamber 302. The transfer mechanism 306 has two independently movable transfer arms 307a and 307b.

A transfer mechanism 308 is provided within the atmospheric transfer chamber 303. The transfer mechanism 308 transfers substrates W to the carrier C, the load lock chamber 302, and the alignment chamber 304.

The film forming apparatus 200 has a control device 310. The operation of the film forming apparatus 200 is controlled by the control device 310. The control device 310 has the same configuration as the control device 110.

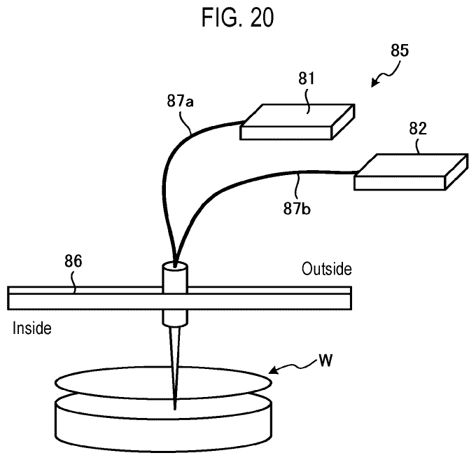

In the film forming apparatus 200 configured as described above, a measurer 85 that performs spectroscopic measurement on the substrate W may be provided in a location other than the chambers 201 to 204. For example, in the film forming apparatus 200, the measurer 85 that performs spectroscopic measurement on the substrate W is provided in any one of the vacuum transfer chamber 301, the load lock chamber 302, the atmospheric transfer chamber 303, and the alignment chamber 304. FIG. 19 is a view showing an example of the schematic configuration of the measurer 85 according to the embodiment. The measurer 85 includes an irradiator 81 that emits light and a detector 82 that can detect light. The irradiator 81 and the detector 82 are located outside a housing 86 of the vacuum transfer chamber 301, the load lock chamber 302, the atmospheric transfer chamber 303, and the alignment chamber 304. Light-guiding members 87a and 87b, such as optical fibers, are connected to the irradiator 81 and the detector 82, respectively. Ends of the light-guiding members 87a and 87b are located within the housing 86. The light output from the irradiator 81 is output from the end of the light-guiding member 87a. The end of the light-guiding member 87a is positioned so that the light is incident on the substrate W at a predetermined angle of incidence (e.g., 45°). The end of the light-guiding member 87b is positioned so that light reflected from the substrate W is incident on the end of the light-guiding member 87b. The light incident on the end of the light-guiding member 87b is detected by the detector 82 via the light-guiding member 87b. The measurer 85 performs spectroscopic measurement on the substrate W to measure the reflectance spectrum of the substrate W. The control device 310 uses a prediction model to determine the filled state of the recesses 91 based on the integral value of reflectance for each wavelength range of the reflectance spectrum of the substrate W measured by the measurer 85. This allows the film forming apparatus 200 to detect in-line filling defects of the recesses 91 of the substrate W. The measurer 85 may perform the spectroscopic measurement by orthogonally irradiating the substrate W with light. FIG. 20 is a view showing another example of the schematic configuration of the measurer 85 according to the embodiment. In FIG. 20, the ends of the light-guiding members 87a and 87b located within the housing 86 are coaxial double optical fibers and are located above substrate W so as to be perpendicular to the substrate W. Light output from the irradiator 81 is output from the end of the light-guiding member 87a and is incident on the substrate W orthogonally. The light incident on the substrate W is reflected and is incident on the end of the light-guiding member 87b. The light incident on the end of the light-guiding member 87b is detected by the detector 82 via the light-guiding member 87b. In this way, the measurer 85 may measure the reflectance spectrum by orthogonally irradiating the substrate W with light and performing the spectroscopic measurement. The control device 310 may use a prediction model to determine the filled state of the recesses 91 based on the integral value of reflectance for each wavelength range of the reflectance spectrum of the substrate W measured by the measurer 85.

Furthermore, if the depth of the recesses 91 in the pattern 90 formed on the substrate W is relatively shallow (e.g., within 0.5 μm), the wavelength range of light used for spectroscopic measurement may be infrared light on the short wavelength side or visible light with a wavelength of approximately 200 μm to 1,000 μm. In this case, it is not necessary to angle the irradiator 81 and the detector 82 and, for example, the spectroscopic measurement may be performed by orthogonally irradiating the substrate W with light, as shown in FIG. 20.

Furthermore, as described above, in the above embodiments, a case has been described as an example in which the substrate processing apparatus of the present disclosure is a single-wafer type substrate processing apparatus of a single-chamber type having one chamber in which substrates W are processed one by one, or of a multi-chamber type having a plurality of chambers. However, the present disclosure is not limited thereto. For example, the substrate processing apparatus of the present disclosure may be a batch-type substrate processing apparatus capable of processing a plurality of substrates at once, or a carousel-type semi-batch-type substrate processing apparatus.

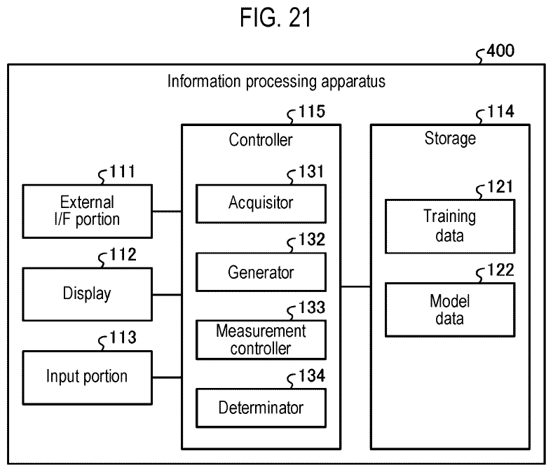

Furthermore, in the above embodiments, a case has been described as an example in which the occurrence of filling defects in the film forming apparatuses 100 and 200 is detected. However, the present disclosure is not limited thereto. The spectroscopic measurement may be performed by a measurer, such as a measurement device that performs spectroscopic measurement which is separate from the film forming apparatuses 100 and 200. Further, the filled state of the recesses 91 may be determined by an information processing apparatus, such as a computer, which is separate from the film forming apparatuses 100 and 200. For example, a substrate W on which a filling material has been formed in the film forming apparatuses 100 and 200 may be transferred to the measurement device, where the spectroscopic measurement may be performed to measure either one of the absorbance spectrum or the reflectance spectrum of the substrate W. The information processing apparatus 400 may acquire data on the one spectrum of the substrate W from the measurement device and determine the filled state of the recesses 91 of the substrate W from the integral value of the spectral value for each wavelength range of the one spectrum of the substrate W indicated by the acquired data. FIG. 21 is a diagram showing an example of a schematic configuration of the information processing apparatus 400 according to an embodiment. The information processing apparatus 400 is partially the same as the control device 110, and therefore, in the following description, the same parts are denoted by the same reference numerals and explanation thereof will be omitted, and differences will be mainly described. The acquisitor 131 acquires data on either one of the absorbance spectrum or the reflectance spectrum of the substrate W from the measurer (measurement device). For example, the acquisitor 131 acquires data on the one spectrum of the substrate W from the measurement device via a network (not shown). The determinator 134 uses a prediction model to determine the filled state of the recesses 91 of the substrate W from the integral value of the spectral value for each wavelength range of the one spectrum of the substrate W indicated by the data acquired by the acquisitor 131. This allows the information processing apparatus 400 according to the embodiment to detect an occurrence of filling defects.

The embodiments disclosed herein should be considered illustrative in all respects and not restrictive. Indeed, the above-described embodiments can be embodied in a variety of forms. Furthermore, the above-described embodiments may be omitted, substituted, or modified in various ways without departing from the scope and spirit of the appended claims.

Furthermore, the following supplementary notes are disclosed regarding the above-described embodiments.

### Supplementary Note 1

A determination method including:
(a) performing spectroscopic measurement of a substrate, in which a pattern including a recess is formed and a filling material is filled in the recess, to measure either one of an absorbance spectrum or a reflectance spectrum of the substrate; and
(b) determining a filled state of the recess from an integral value of a spectral value for each wavelength range of a plurality of wavelength ranges of the one spectrum of the substrate measured in step (a), by using a model generated by performing machine learning on data associating a plurality of filled states of recesses with integral values of spectral values for each wavelength range of the one spectrum of a plurality of substrates in which the filling material is filled.

### Supplementary Note 2

The determination method of Supplementary Note 1, further including: before step (a) and step (b),
(c) performing spectroscopic measurement of the plurality of substrates filled with the filling material to measure the one spectrum of the plurality of substrates;
(d) acquiring a first index value that indexes the filled state of the recess of each of the plurality of substrates; and
(e) generating the model by performing machine learning on data associating, for each of the plurality of substrates, the first index values acquired in step (d) with the integral values of spectral values for each wavelength range of the one spectrum measured in step (c),
wherein, in step (b), using the integral value of the spectral value for each wavelength range of the one spectrum of the substrate measured in step (a) as an explanatory variable and the first index value as an objective variable, the first index value is derived from the model generated in step (e), and the filled state of the recess is determined based on the derived first index value.

### Supplementary Note 3

The determination method of Supplementary Note 2, wherein, in step (e), machine learning is performed using a linear regression algorithm to generate the model that learns a relationship between the integral values of the spectral values for each wavelength range and the first index values.

### Supplementary Note 4

The determination method of Supplementary Note 2 or 3, further including: before step (e),
(f) acquiring a film thickness of the filling material of each of the plurality of substrates filled with the filling material,
wherein, in step (e), the model is generated by performing machine learning on data associating, for each of the plurality of substrates, the integral values of the spectral values for each wavelength range of the one spectrum measured in step (c), the first index value acquired in step (d), and the film thickness acquired in step (f), and
wherein, in step (b), using the integral value of the spectral value for each wavelength range of the one spectrum of the substrate measured in step (a) as an explanatory variable and the first index value and the film thickness as objective variables, the first index value and the film thickness are derived from the model generated in step (e).

### Supplementary Note 5

The determination method of any one of Supplementary Notes 2 to 4, further including: before step (e),
(g) acquiring a second index value that indexes a base state of each of the plurality of substrates filled with the filling material,
wherein, in step (e), the model is generated by performing machine learning on data associating, for each of the plurality of substrates, the integral values of the spectral values for each wavelength range of the one spectrum measured in step (c), the first index value acquired in step (d), and the second index value acquired in step (g), and
wherein, in step (b), using the integral value of the spectral value for each wavelength range of the one spectrum of the substrate measured in step (a) and the second index value as explanatory variables and the first index value as an objective variable, the first index value is derived from the model generated in step (e).

### Supplementary Note 6

The determination method of any one of Supplementary Notes 1 to 5, wherein a width of each of the plurality of wavelength ranges is in a range of 75 to 200 nm.

### Supplementary Note 7

The determination method of any one of Supplementary Notes 1 to 6, wherein the plurality of wavelength ranges is set so that the wavelengths are continuous.

### Supplementary Note 8

The determination method of any one of Supplementary Notes 1 to 7, wherein the plurality of wavelength ranges is set to a wavelength range of 200 to 700 nm.

### Supplementary Note 9

A non-transitory computer-readable storage medium storing a determination program that causes a computer to perform a process including:
(a) performing spectroscopic measurement of a substrate, in which a pattern including a recess is formed and a filling material is filled in the recess, to measure either one of an absorbance spectrum or a reflectance spectrum of the substrate; and
(b) determining a filled state of the recess from an integral value of a spectral value for each wavelength range of a plurality of wavelength ranges of the one spectrum of the substrate measured in step (a), by using a model generated by performing machine learning on data associating a plurality of filled states of recesses with integral values of spectral values for each wavelength range of the one spectrum of a plurality of substrates in which the filling material is filled.

### Supplementary Note 10

A substrate processing apparatus including:
a measurer configured to perform spectroscopic measurement of a substrate, in which a pattern including a recess is formed and a filling material is filled in the recess, to measure either one of an absorbance spectrum or a reflectance spectrum of the substrate; and
a determinator configured to determine a filled state of the recess from an integral value of a spectral value for each wavelength range of a plurality of wavelength ranges of the one spectrum of the substrate measured by the measurer, by using a model generated by performing machine learning on data associating a plurality of filled states of recesses with integral values of spectral values for each wavelength range of the one spectrum of a plurality of substrates in which the filling material is filled.

### Supplementary Note 11

An information processing apparatus including:
an acquisitor configured to acquire, from a measurer that performs spectroscopic measurement of a substrate in which a pattern including a recess is formed and a filling material is filled in the recess, to measure either one of an absorbance spectrum or a reflectance spectrum of the substrate, data on the one spectrum of the substrate; and
a determinator configured to determine a filled state of the recess from an integral value of a spectral value for each wavelength range of a plurality of wavelength ranges of the one spectrum of the substrate indicated in the data acquired by the acquisitor, by using a model generated by performing machine learning on data associating a plurality of filled states of recesses with integral values of spectral values for each wavelength range of the one spectrum of a plurality of substrates in which the filling material is filled.

According to the present disclosure in some embodiments, it is possible to detect the occurrence of filling defects.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A determination method comprising:
(a) performing spectroscopic measurement of a substrate, in which a pattern including a recess is formed and a filling material is filled in the recess, to measure either one of an absorbance spectrum or a reflectance spectrum of the substrate; and
(b) determining a filled state of the recess from an integral value of a spectral value for each wavelength range of a plurality of wavelength ranges of the one spectrum of the substrate measured in step (a), by using a model generated by performing machine learning on data associating a plurality of filled states of recesses with integral values of spectral values for each wavelength range of the one spectrum of a plurality of substrates in which the filling material is filled.

2. The determination method of claim 1, further comprising: before step (a) and step (b),
(c) performing spectroscopic measurement of the plurality of substrates filled with the filling material to measure the one spectrum of the plurality of substrates;
(d) acquiring a first index value that indexes the filled state of the recess of each of the plurality of substrates; and
(e) generating the model by performing machine learning on data associating, for each of the plurality of substrates, the first index values acquired in step (d) with the integral values of spectral values for each wavelength range of the one spectrum measured in step (c),
wherein, in step (b), using the integral value of the spectral value for each wavelength range of the one spectrum of the substrate measured in step (a) as an explanatory variable and the first index value as an objective variable, the first index value is derived from the model generated in step (e), and the filled state of the recess is determined based on the derived first index value.

3. The determination method of claim 2, wherein, in step (e), machine learning is performed using a linear regression algorithm to generate the model that learns a relationship between the integral values of the spectral values for each wavelength range and the first index values.

4. The determination method of claim 2, further comprising: before step (e),
(f) acquiring a film thickness of the filling material of each of the plurality of substrates filled with the filling material,
wherein, in step (e), the model is generated by performing machine learning on data associating, for each of the plurality of substrates, the integral values of the spectral values for each wavelength range of the one spectrum measured in step (c), the first index value acquired in step (d), and the film thickness acquired in step (f), and
wherein, in step (b), using the integral value of the spectral value for each wavelength range of the one spectrum of the substrate measured in step (a) as an explanatory variable and the first index value and the film thickness as objective variables, the first index value and the film thickness are derived from the model generated in step (e).

5. The determination method of claim 2, further comprising: before step (e),
(g) acquiring a second index value that indexes a base state of each of the plurality of substrates filled with the filling material,
wherein, in step (e), the model is generated by performing machine learning on data associating, for each of the plurality of substrates, the integral values of the spectral values for each wavelength range of the one spectrum measured in step (c), the first index value acquired in step (d), and the second index value acquired in step (g), and
wherein, in step (b), using the integral value of the spectral value for each wavelength range of the one spectrum of the substrate measured in step (a) and the second index value as explanatory variables and the first index value as an objective variable, the first index value is derived from the model generated in step (e).

6. The determination method of claim 1, wherein a width of each of the plurality of wavelength ranges is in a range of 75 to 200 nm.

7. The determination method of claim 1, wherein the plurality of wavelength ranges is set so that the wavelengths are continuous.

8. The determination method of claim 1, wherein the plurality of wavelength ranges is set to a wavelength range of 200 to 700 nm.

9. A non-transitory computer-readable storage medium storing a determination program that causes a computer to perform a process comprising:
(a) performing spectroscopic measurement of a substrate, in which a pattern including a recess is formed and a filling material is filled in the recess, to measure either one of an absorbance spectrum or a reflectance spectrum of the substrate; and
(b) determining a filled state of the recess from an integral value of a spectral value for each wavelength range of a plurality of wavelength ranges of the one spectrum of the substrate measured in step (a), by using a model generated by performing machine learning on data associating a plurality of filled states of recesses with integral values of spectral values for each wavelength range of the one spectrum of a plurality of substrates in which the filling material is filled.

10. A substrate processing apparatus comprising:
a measurer configured to perform spectroscopic measurement of a substrate, in which a pattern including a recess is formed and a filling material is filled in the recess, to measure either one of an absorbance spectrum or a reflectance spectrum of the substrate; and
a determinator configured to determine a filled state of the recess from an integral value of a spectral value for each wavelength range of a plurality of wavelength ranges of the one spectrum of the substrate measured by the measurer, by using a model generated by performing machine learning on data associating a plurality of filled states of recesses with integral values of spectral values for each wavelength range of the one spectrum of a plurality of substrates in which the filling material is filled.

11. An information processing apparatus comprising:
an acquisitor configured to acquire, from a measurer that performs spectroscopic measurement of a substrate in which a pattern including a recess is formed and a filling material is filled in the recess, to measure either one of an absorbance spectrum or a reflectance spectrum of the substrate, data on the one spectrum of the substrate; and
a determinator configured to determine a filled state of the recess from an integral value of a spectral value for each wavelength range of a plurality of wavelength ranges of the one spectrum of the substrate indicated in the data acquired by the acquisitor, by using a model generated by performing machine learning on data associating a plurality of filled states of recesses with integral values of spectral values for each wavelength range of the one spectrum of a plurality of substrates in which the filling material is filled.
